(19) United States
(12) Patent Application Publication
(10) Pub. No.: US 2025/0087617 A1
(43) Pub. Date: Mar. 13, 2025

(54) SEMICONDUCTOR PACKAGE

(71) Applicant: NEPES CO., LTD., Samseong-myeon (KR)

(72) Inventors: Dong Hoon OH, Samseong-myeon (KR); Yong Tae KWON, Samseong-myeon (KR); Seong Hyuk LEE, Samseong-myeon (KR); Seong Hwan HAN, Samseong-myeon (KR); Hyeon Jun LEE, Samseong-myeon (KR)

(21) Appl. No.: 18/527,792

(22) Filed: Dec. 4, 2023

(30) Foreign Application Priority Data
Dec. 5, 2022 (KR) 10-2022-0168091

(51) Int. Cl. H01L 23/00; H01L 23/31; H01L 23/552; H01L 25/00; H01L 25/10

(52) U.S. Cl. CPC H01L 24/24; H01L 23/552; H01L 24/20; H01L 24/25; H01L 25/105; H01L 25/50; H01L 23/3185; H01L 2224/2105; H01L 2224/214; H01L 2224/24105; H01L 2224/24146; H01L 2224/2518

(57) ABSTRACT

The technical idea of the present invention provides a semiconductor package having improved performance and reliability while simplifying a process. The semiconductor package according the technical idea of the present invention includes a first package including a first semiconductor chip, a first encapsulation layer covering a side surface of the first semiconductor chip, and a first redistribution pattern connected to a pad of the first semiconductor chip, and a second package provided on the first package and including a second semiconductor chip, a second encapsulation layer covering the second semiconductor chip, and a second redistribution pattern connected to a pad of the second semiconductor chip, wherein the first redistribution pattern is connected to the second redistribution pattern through the first encapsulation layer.

### BACKGROUND

### 1. Field of the Invention

The technical idea of the present invention relates to a semiconductor package, and more particularly, to a semiconductor package with improved reliability while simplifying a manufacturing process.

### 2. Discussion of Related Art

In general, a semiconductor package is formed by performing a packaging process on semiconductor chips formed by performing various semiconductor processes on a wafer. Recently, semiconductor packages are becoming more and more highly integrated, while still requiring high reliability and high heat dissipation characteristics.

### SUMMARY OF THE INVENTION

The present invention is directed to providing a semiconductor package with improved performance and reliability while simplifying a process.

According to an aspect of the present invention, there is provided a semiconductor package including a first package including a first semiconductor chip, a first encapsulation layer covering a side surface of the first semiconductor chip, and a first redistribution pattern connected to a pad of the first semiconductor chip, and a second package provided on the first package and including a second semiconductor chip, a second encapsulation layer covering the second semiconductor chip, and a second redistribution pattern connected to a pad of the second semiconductor chip, wherein the first redistribution pattern is connected to the second redistribution pattern through the first encapsulation layer.

In one embodiment of the present invention, the first encapsulation layer may include a first surface and a second surface opposite to each other, and a through hole passing through the first surface and the second surface, the first redistribution pattern may include a first portion extending from the first surface to the second surface through the through hole and a second portion connected to the first portion and extending on the first surface, and a first thickness of the first portion located on the first surface may be greater than a second thickness of the first portion located on the second surface.

In one embodiment of the present invention, the first encapsulation layer may include a first surface and a second surface opposite to each other, and a through hole passing through the first surface and the second surface, and the first redistribution pattern may include a first conductive layer disposed on an inner surface of the through hole and connected to the second package, and a second conductive layer disposed on the first surface and connected to the first conductive layer and the pad of the first semiconductor chip.

In one embodiment of the present invention, the second package may further include a second redistribution pattern connected to the pad of the second semiconductor chip, the first encapsulation layer may include a first surface and a second surface opposite to each other, and a through hole passing through the first surface and the second surface, and the first redistribution pattern may be connected to the pad of the second semiconductor chip by being directly connected to the second redistribution pattern through the through hole.

In one embodiment of the present invention, the semiconductor package may further include an electromagnetic wave shielding layer covering at least a portion of the first package and at least a portion of the second package.

In one embodiment of the present invention, the semiconductor package may further include an outer encapsulation layer covering the first package, the second package, and the electromagnetic wave shielding layer.

In one embodiment of the present invention, the semiconductor package may further include a lower conductive layer extending on the first package and the outer encapsulation layer, wherein the lower conductive layer may be electrically connected to the first redistribution pattern of the first package and the electromagnetic wave shielding layer.

In one embodiment of the present invention, the semiconductor package may further include a thermal conductive film provided on the first package and the outer encapsulation layer and covering at least a portion of the lower conductive layer.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a cross-sectional view illustrating a semiconductor package according to exemplary embodiments of the present invention;

FIG. 2 is an enlarged cross-sectional view of portion A of FIG. 1;

FIG. 3 is a view illustrating various shapes of the semiconductor package according to an exemplary embodiment of the present invention;

FIGS. 4A to 4E are cross-sectional views illustrating a method of manufacturing the semiconductor package according to exemplary embodiments of the present invention;

FIG. 5 is a cross-sectional view illustrating a semiconductor package according to exemplary embodiments of the present invention;

FIG. 6 is a cross-sectional view illustrating a semiconductor package according to exemplary embodiments of the present invention;

FIGS. 7A to 7F are cross-sectional views illustrating a method of manufacturing the semiconductor package according to exemplary embodiments of the present invention;

FIG. 8 is a cross-sectional view illustrating a semiconductor package according to exemplary embodiments of the present invention;

FIG. 9 is a cross-sectional view illustrating a semiconductor package according to exemplary embodiments of the present invention;

FIG. 10A is a cross-sectional view illustrating a semiconductor package according to exemplary embodiments of the present invention;

FIG. 10B is a cross-sectional view illustrating the semiconductor package taken along line 10B-10B′ of FIG. 10A;

FIG. 11 is a cross-sectional view illustrating a semiconductor package according to exemplary embodiments of the present invention;

FIG. 12 is a cross-sectional view illustrating a semiconductor package according to exemplary embodiments of the present invention;

FIG. 13 is a flowchart illustrating operations of a method of manufacturing the semiconductor package according to exemplary embodiments of the present invention;

FIGS. 14 to 25 are cross-sectional views illustrating the method of manufacturing the semiconductor package according to exemplary embodiments of the present invention;

FIG. 26 illustrates a photograph and an enlarged photograph obtained by photographing a portion of operations of the method of manufacturing the semiconductor package according to exemplary embodiments of the present invention;

FIG. 27 illustrates a photograph and an enlarged photograph obtained by photographing a portion of operations of a method of manufacturing another semiconductor package according to a comparative example of the embodiment;

FIG. 28 is a cross-sectional view illustrating a semiconductor package according to an exemplary embodiment of the present invention;

FIGS. 29A to 291 are cross-sectional views illustrating a method of manufacturing the semiconductor package according to exemplary embodiments of the present invention;

FIG. 30 is a cross-sectional view illustrating a semiconductor package according to an exemplary embodiment of the present invention;

FIGS. 31A to 31E are cross-sectional views illustrating a method of manufacturing the semiconductor package according to exemplary embodiments of the present invention; and

FIGS. 32 to 35 are cross-sectional views each illustrating a semiconductor package according to an exemplary embodiment of the present invention.

### DETAILED DESCRIPTION OF EXEMPLARY EMBODIMENTS

General terms that are currently widely used were selected as terms used in embodiments in consideration of functions in the present invention, but may be changed depending on the intention of those skilled in the art or a judicial precedent, the emergence of a new technique, and the like. In addition, in a specific case, terms arbitrarily chosen by an applicant may exist, and in this case, the meaning of such terms will be described in detail in a corresponding description portion of the invention. Accordingly, the terms used in the present invention should be defined on the basis of the meaning of the terms and the contents throughout the present invention rather than simple names of the terms.

The terms first, second, or the like may be used to describe various components, but the components are not limited by the terms. The terms are used only for the purpose of distinguishing one component from another. For example, without departing from the scope of the present inventive concept, a first component may be referred to as a second component, and, conversely, a second component may be referred to as a first component.

The term used herein is for the purpose of describing particular embodiments only and is not intended to be limiting of the present inventive concept. A singular expression includes a plural expression unless the context clearly indicates otherwise. In the present application, terms such as “include” or “have” are used to describe that features, numbers, steps, operations, components, parts, or combinations thereof are present and do not preclude the possibility of presence or addition of one or more other features, numbers, steps, operations, components, parts, or combinations thereof in advance.

In the following description, when a component is described as being connected to another component, the component may be directly connected to the another component, but a third component may be interposed therebetween. Similarly, when a component is described as being present on another component, the component may be directly on the another component, or a third component may be interposed therebetween. In addition, in the drawings, the structure or size of each component has been exaggerated for convenience and clarity of the description, and parts not related to the description are omitted.

Unless otherwise defined, all terms used herein have the same meaning as commonly understood by one of ordinary skill in the art to which the present inventive concept pertains, and have the same meaning as commonly understood by one of ordinary skill in the art to which the present inventive concept pertains. Further, it will be further understood that terms, such as those defined in commonly used dictionaries, should be interpreted as having meanings that are consistent with their meanings in the context of the relevant art and/or the present specification, and should not be interpreted in an overly formal sense, unless expressly defined herein.

Hereinafter, a semiconductor package according to one embodiment of the present invention will be described with reference to the accompanying drawings.

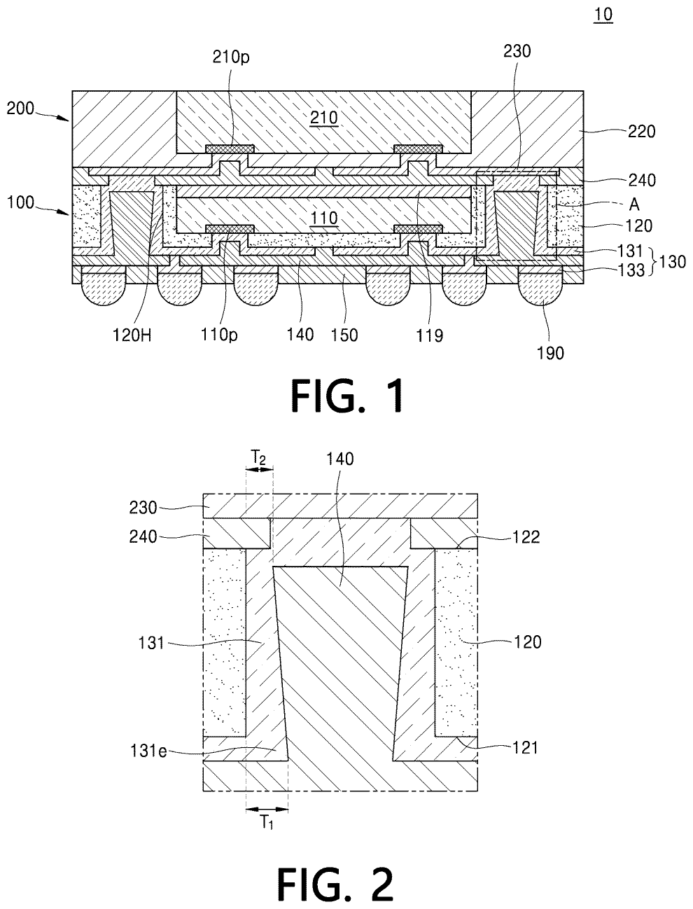

FIG. 1 is a cross-sectional view illustrating a semiconductor package according to exemplary embodiments of the present invention.

Referring to FIG. 1, a semiconductor package 10 may include a first package 100 and a second package 200. The semiconductor package 10 may be, for example, a package-on-package (POP)-type semiconductor package in which the second package 200 is attached onto the first package 100. In addition, the semiconductor package 10 may also be, for example, a three-dimensional (3D) stacked semiconductor package, or a system-in-package (SIP)-type semiconductor package in which each layer having various functions is stacked, or connected side by side.

The first package 100 may be, for example, a fan-out wafer level package (FOWLP) type semiconductor package.

The first package 100 may include a first semiconductor chip 110. A semiconductor substrate forming the first semiconductor chip 110 may include, for example, silicon (Si). Alternatively, the semiconductor substrate forming the first semiconductor chip 110 may include, for example, a semiconductor element such as germanium (Ge) or a compound semiconductor such as silicon carbide (SiC), gallium arsenide (GaAs), indium arsenide (InAs), and indium phosphide (InP). Alternatively, the semiconductor substrate forming the first semiconductor chip 110 may have a silicon-on-insulator (SOI) structure.

The semiconductor substrate forming the first semiconductor chip 110 may have an active surface and an inactive surface opposite to the active surface. In the first semiconductor chip 110, a semiconductor device including a plurality of various types of individual devices may be formed on the active surface. The plurality of individual devices may include various types of microelectronics devices, e.g., metal-oxide-semiconductor field effect transistors (MOSFETs) such as a complementary metal-insulator-semiconductor (CMOS) transistor, system large-scale integration (LSI), an image sensor such as a CMOS imaging sensor (CIS), a micro-electro-mechanical system (MEMS), an active device, a passive device, and the like.

The first semiconductor chip 110 may include a plurality of pads 110p. The plurality of pads 110p may be electrically connected to the semiconductor device included in the first semiconductor chip 110. The first semiconductor chip 110 may be a single semiconductor chip, but the present invention is not limited thereto. For example, the first semiconductor chip 110 may be a stack of a plurality of semiconductor chips.

In exemplary embodiments, the first semiconductor chip 110 may be, for example, a memory semiconductor chip. The memory semiconductor chip may be, for example, a volatile memory semiconductor chip, such as a dynamic random access memory (DRAM) or a static random access memory (SRAM), or a nonvolatile memory semiconductor chip, such as a phase-change random access memory (PRAM), a magnetoresistive random access memory (MRAM), a ferroelectric random access memory (FeRAM), or a resistive random access memory (RRAM).

Alternatively, in exemplary embodiments, the first semiconductor chip 110 may be a logic chip. For example, the first semiconductor chip 110 may be an artificial intelligence (AI) processor, a central processor unit (CPU), a micro processor unit (MPU), a graphics processor unit (GPU), or an application processor (AP).

The first package 100 may include a first encapsulation layer 120 covering at least a portion of the first semiconductor chip 110. The first encapsulation layer 120 covers a side surface of the first semiconductor chip 110, and may cover a lower surface of the first semiconductor chip 110, on which the pads 110p are provided. The first encapsulation layer 120 may have openings for exposing the pads 110p of the first semiconductor chip 110.

The first encapsulation layer 120 may include an insulating material. In exemplary embodiments, the first encapsulation layer 120 may include a photosensitive material. For example, the first encapsulation layer 120 may be formed of a polymer material such as polyimide. However, the material forming the first encapsulation layer 120 is not limited thereto, and for example, the first encapsulation layer 120 may include an epoxy molding compound (EMC).

The first encapsulation layer 120 may include through holes 120H vertically passing through the first encapsulation layer 120. The through holes 120H may be provided in peripheral portions of the first semiconductor chip 110. A ratio of a height of the through hole 120H and a width of the through hole 120H may be formed to be about 1:1.

The first package 100 may include first redistribution structures 130 and 140 provided on the first semiconductor chip 110. The first redistribution structures 130 and 140 may include a first redistribution pattern 130 and a first insulating pattern 140.

The first redistribution pattern 130 may electrically connect the pads 110p of the first semiconductor chip 110 to external connection terminals 190. In addition, the first redistribution pattern 130 may be electrically connected to a second redistribution pattern 230. Through the first redistribution pattern 130 and the second redistribution pattern 230, the first semiconductor chip 110 may be electrically connected to a second semiconductor chip 210, and the second semiconductor chip 210 may be electrically connected to the external connection terminals 190.

More specifically, the first redistribution pattern 130 may include a plurality of sub-redistribution patterns, and the sub-redistribution patterns may have a multilayer structure. For example, the first redistribution pattern 130 may include a first sub-redistribution pattern 131 and a second sub-redistribution pattern 133. The first sub-redistribution pattern 131 is formed on the first encapsulation layer 120, and may be connected to the pad 110p of the first semiconductor chip 110. A portion of the first sub-redistribution pattern 131 may be connected to the second redistribution pattern 230 through the first encapsulation layer 120 and a second insulating pattern 240. The second sub-redistribution pattern 133 extends on the first insulating pattern 140, and may be connected to the first sub-redistribution pattern 131 through the first insulating pattern 140.

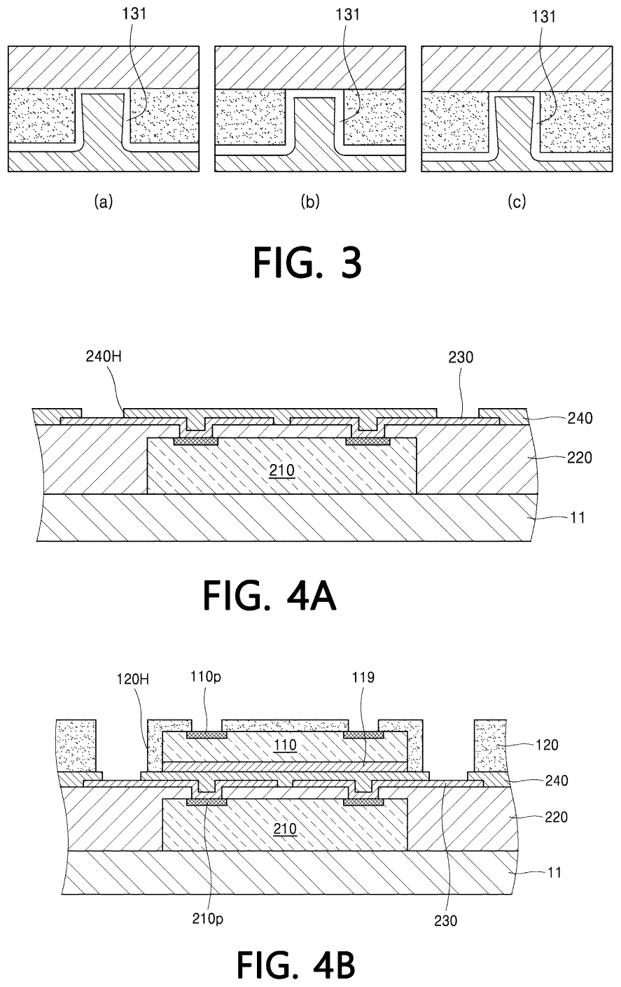

FIG. 2 is an enlarged cross-sectional view of portion A of FIG. 1.

Referring to FIG. 2, the first sub-redistribution pattern 131 may include a first portion extending in the through hole 120H, and a second portion connected to the first portion and extending on the first encapsulation layer 120.

In exemplary embodiments of the present invention, a thickness of the first portion of the first sub-redistribution pattern 131 may have a size that is not constant in a direction in which the through hole 120H extends. That is, the thickness of the first portion of the first sub-redistribution pattern 131 disposed in the through hole 120H may have a size changed in the direction in which the through hole 120H extends. The direction in which the through hole 120H extends may be a direction from a first surface 121 of the first encapsulation layer 120 toward a second surface 122 of the first encapsulation layer 120.

In addition, a thickness of the second portion of the first sub-redistribution pattern 131, which is not disposed in the through hole 120H, may have a constant size in a direction in which the first encapsulation layer 120 extends.

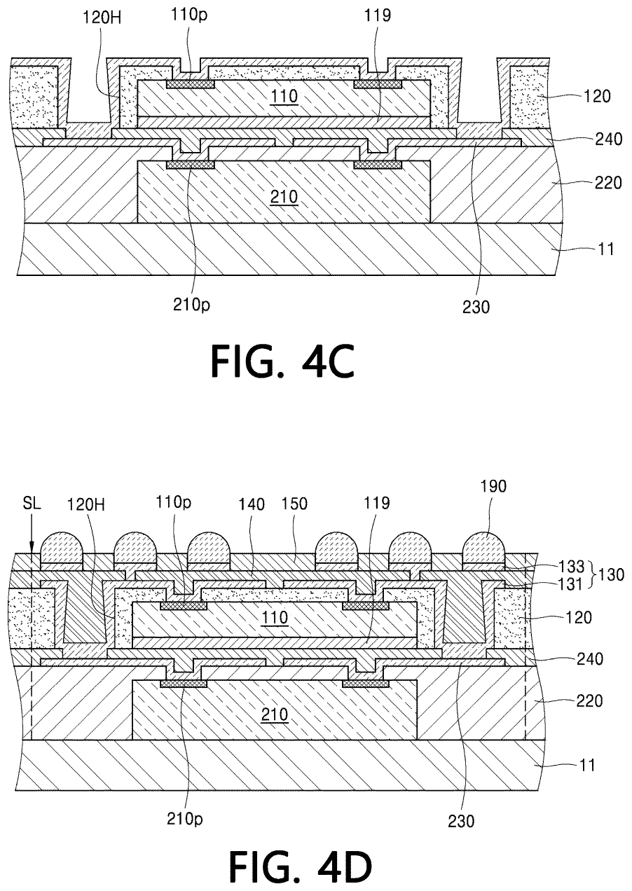

FIG. 3 is a view illustrating various shapes of the semiconductor package according to an exemplary embodiment of the present invention.

Referring to FIGS. 2 and 3, in exemplary embodiments, a first thickness T₁ of the first sub-redistribution pattern 131 located on the first surface 121 of the first encapsulation layer 120 may be greater than a second thickness T₂ of the first sub-redistribution pattern 131 located on the second surface 122 of the first encapsulation layer 120. The first thickness T₁ and the second thickness T₂ may be sizes of the first portion based on a direction in which the first encapsulation layer 120 extends.

In general, during a subsequent process of forming the first sub-redistribution pattern 131 on the first encapsulation layer 120 and forming the second sub-redistribution pattern 133 and the first insulating pattern 140 on the first sub-redistribution pattern 131, a phenomenon in which a stress is concentrated on an edge 131e (shown in FIG. 2) of the first sub-redistribution pattern 131 may occur. This is because that the process is performed in a state in which the edge 131e of the first sub-redistribution pattern 131 is not filled with the same material as the first encapsulation layer 120. Thus, due to the stress concentrated on the edge 131e of the first sub-redistribution pattern 131, a delamination phenomenon in which the first sub-redistribution pattern 131 is separated from the first encapsulation layer 120 occurs, and thus, an electrical short circuit phenomenon or the like occurs, thereby reducing the performance of the semiconductor package 10.

According to exemplary embodiments of the present invention, the semiconductor package 10 may be implemented in a structure capable of withstanding stress concentrated on the edge 131e by increasing a thickness of the edge 131e of the first sub-redistribution pattern 131, on which stress is concentrated. Accordingly, the possibility of a delamination phenomenon in which the first sub-redistribution pattern 131 is separated from the first encapsulation layer 120 may be reduced, and thus, an electrical short circuit phenomenon or the like may be prevented, thereby improving the performance and reliability of the semiconductor package 10. FIG. 3A to FIG. 3C illustrate various shapes of the first sub-redistribution pattern 131 in an exemplary embodiment of the present invention.

In addition, according to exemplary embodiments of the present invention, the first sub-redistribution pattern 131 is formed with a constant thickness in the second portion except for the portion disposed in the through hole 120H. Thus, while the possibility of a delamination phenomenon may be reduced due to the first portion including the edge 131e formed with a large thickness, process costs may be reduced and the process may be simplified due to the second portion having a constant thickness.

In exemplary embodiments, a ratio of a size of the first thickness T₁ to a size of the second thickness T₂ may be 1:0.1 to 1:0.9, 1:0.2 to 1:0.7, or 1:0.3 to 1:0.52.

In exemplary embodiments, the thickness of the first portion of the first sub-redistribution pattern 131 may be gradually reduced in a direction from the first surface 121 of the first encapsulation layer 120 toward the second surface 122 of the first encapsulation layer 120.

The first insulating pattern 140 may be provided on a lower surface of the first encapsulation layer 120. The first insulating pattern 140 covers the first sub-redistribution pattern 131, and may have openings exposing portions of the first sub-redistribution pattern 131.

A protective layer 150 may be formed on the first insulating pattern 140. The protective layer 150 may expose a portion of the second sub-redistribution pattern 133. The external connection terminal 190 may be disposed in the portion of the second sub-redistribution pattern 133 exposed by the protective layer 150. The external connection terminal 190 may be, for example, a solder ball or bump. The external connection terminals 190 may electrically connect between the semiconductor package 10 and an external device.

The second package 200 may be disposed on the first package 100. The second package 200 may include the second semiconductor chip 210. The second semiconductor chip 210 may include pads 210p. The second semiconductor chip 210 may be a single semiconductor chip, but the present invention is not limited thereto. For example, the second semiconductor chip 210 may be a stack of a plurality of semiconductor chips.

In exemplary embodiments, the second semiconductor chip 210 may be, for example, a memory semiconductor chip. Alternatively, in exemplary embodiments, the second semiconductor chip 210 may be a logic chip.

The second package 200 may include a second encapsulation layer 220 covering at least a portion of the second semiconductor chip 210. For example, the second encapsulation layer 220 covers a side surface of the second semiconductor chip 210, and may cover a lower surface of the second semiconductor chip 210 on which the pads 210p are formed. The second encapsulation layer 220 may have openings for exposing the pads 210p of the second semiconductor chip 210. In this case, the second encapsulation layer 220 may not cover an upper surface of the second semiconductor chip 210 opposite to the lower surface of the second semiconductor chip 210.

The second encapsulation layer 220 may include an insulating material. In exemplary embodiments, the second encapsulation layer 220 may include a photosensitive material. For example, the second encapsulation layer 220 may be formed of a polymer material such as polyimide. However, the material forming the second encapsulation layer 220 is not limited thereto, and for example, the second encapsulation layer 220 may include an EMC.

The second package 200 may include second redistribution structures 230 and 240 provided between the second encapsulation layer 220 and the first encapsulation layer 120. The second redistribution structures 230 and 240 may include the second redistribution pattern 230 and the second insulating pattern 240. The second redistribution pattern 230 may extend along a surface of the second encapsulation layer 220 and may be electrically connected to the pads 210p of the second semiconductor chip 210.

In embodiments of the present invention, an electrical connection between the second package 200 and the first package 100 may be made through a connection between the first redistribution pattern 130 and the second redistribution pattern 230. The semiconductor package 10 does not include inter-package connection terminals such as solder balls for connecting the second package 200 and the first package 100, and thus, semiconductor package manufacturing processes may be simplified and a thinner PoP-type semiconductor package may be manufactured.

In general, in the case of a PoP-type semiconductor package in which a plurality of packages are stacked, due to warpage of the semiconductor package, damage such as cracks occurs in the inter-package connection terminals, which may reduce the reliability of the semiconductor package. However, according to exemplary embodiments of the present invention, since the second package 200 and the first package 100 may be electrically connected without the inter-package connection terminals vulnerable to warpage, the reliability of the semiconductor package 10 may be improved.

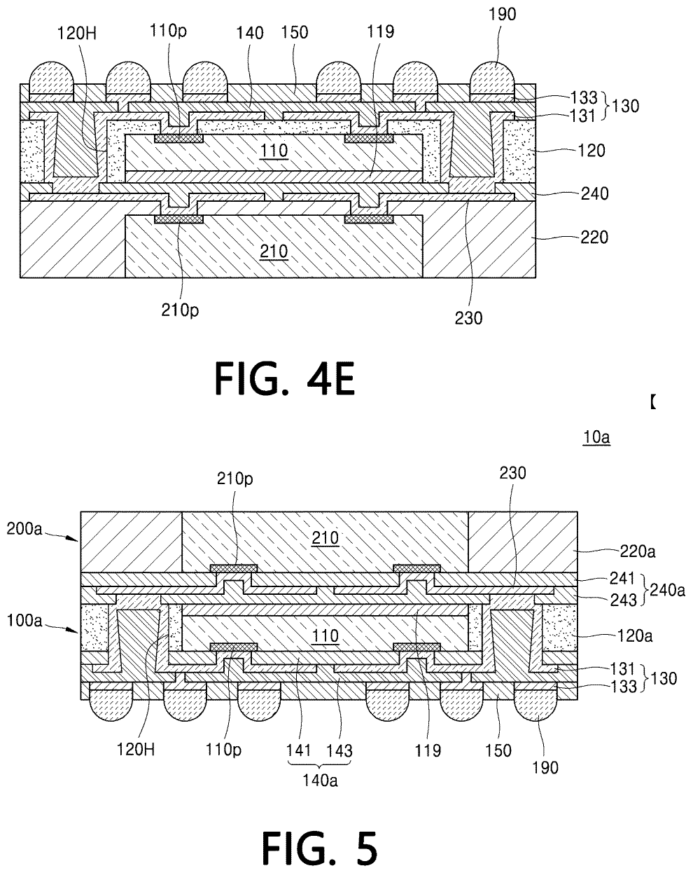

FIGS. 4A to 4E are cross-sectional views illustrating a method of manufacturing the semiconductor package according to exemplary embodiments of the present invention. In FIGS. 4A to 4E, a method of manufacturing the semiconductor package 10 illustrated in FIG. 1 will be described.

Referring to FIG. 4A, a second semiconductor chip 210 is disposed on a carrier 11 and a second encapsulation layer 220 that covers the second semiconductor chip 210 is formed. The second encapsulation layer 220 may be formed to cover a side surface of the second semiconductor chip 210 and a surface of the second semiconductor chip 210 on which pads 210p are provided. In exemplary embodiments, in order to form the second encapsulation layer 220, an insulating film is coated on the carrier 11 and the second semiconductor chip 210 and portions of the insulating film may be removed so that the pads 210p of the second semiconductor chip 210 are exposed. The insulating film may include, for example, a photosensitive material.

After forming the second encapsulation layer 220, second redistribution structures 230 and 240 may be formed on the second encapsulation layer 220 and the second semiconductor chip 210. Specifically, a second redistribution pattern 230 may be formed on the second encapsulation layer 220 and the pads 210p of the second semiconductor chip 210. For example, the second redistribution pattern 230 may be formed through a seed film forming process, a mask process, and an electroplating process. After forming the second redistribution pattern 230, in order to form the second insulating pattern 240, an insulating film may be formed on the second encapsulation layer 220 and the second redistribution pattern 230 and portions of the insulating film may be removed so that openings 240H for exposing portions of the second redistribution pattern 230 are formed.

Referring to FIG. 4B, A first semiconductor chip 110 is disposed on the second insulating pattern 240. An adhesive layer 119 for fixing the first semiconductor chip 110 may be provided between the first semiconductor chip 110 and the second insulating pattern 240. The adhesive layer 119 may include, for example, a die attach film. In addition, the adhesive layer 119 may include a material having high thermal conductivity so that heat of the first semiconductor chip 110 may be effectively emitted.

After disposing the first semiconductor chip 110, a first encapsulation layer 120 covering the first semiconductor chip 110 may be formed. The first encapsulation layer 120 may be formed to have openings for exposing pads 110p of the first semiconductor chip 110, and may be formed to have through holes 120H that pass through the first encapsulation layer 120 so as to expose the second redistribution pattern 230. In order to form the first encapsulation layer 120, an insulating film is coated on the carrier 11 and the second semiconductor chip 210, portions of the insulating film are removed so that the pads 210p of the second semiconductor chip 210 are exposed, and the through holes 120H vertically passing through the insulating film may be formed so that the second redistribution pattern 230 is exposed.

In exemplary embodiments of the present invention, the first encapsulation layer 120 is formed by a lamination process using a polymer material such as polyimide and may cover the side surface of the first semiconductor chip 110 and the surface of the first semiconductor chip 110 on which the pads 110p are provided. In this case, in comparison with the case in which an operation of forming a mold material that covers the side surface of the first semiconductor chip 110 and an operation of sequentially forming insulating materials on the lower surface of the first semiconductor chip 110 are performed, the first encapsulation layer 120 that covers the side surface of the first semiconductor chip 110 and the surface of the first semiconductor chip 110 may be formed by a single lamination process, so that semiconductor package manufacturing processes may be simplified.

Referring to FIGS. 4C and 4D, the first redistribution structures 130 and 140 may be formed on the first encapsulation layer 120 and the first semiconductor chip 110.

First, as shown in FIG. 4C, a first sub-redistribution pattern 131 may be formed on the first encapsulation layer 120 and the first semiconductor chip 110. The first sub-redistribution pattern 131 may be formed on the first encapsulation layer 120, may be in contact with the pads 110p of the first semiconductor chip 110, and may extend along the through holes 120H of the first encapsulation layer 120 to be in contact with the second redistribution pattern 230. For example, the first sub-redistribution pattern 131 may be formed through a seed film forming process, a mask process, and an electroplating process.

In a process of forming the first sub-redistribution pattern 131 on the first encapsulation layer 120 and the first semiconductor chip 110, a first portion of the first sub-redistribution pattern 131 may be formed such that a thickness thereof has a size changed in a direction in which the through hole 120H extends. In addition, a thickness of a second portion of the first sub-redistribution pattern 131 may have a constant size in a direction in which the first encapsulation layer 120 extends.

In exemplary embodiments, a first thickness T₁ of the first sub-redistribution pattern 131 located on the first surface 121 of the first encapsulation layer 120 may be greater than a second thickness T₂ of the first sub-redistribution pattern 131 located on the second surface 122 of the first encapsulation layer 120.

According to exemplary embodiments of the present invention, the semiconductor package 10 may be implemented in a structure capable of withstanding stress by increasing a thickness of the edge 131e of the first sub-redistribution pattern 131, on which stress is concentrated. Accordingly, the possibility of a delamination phenomenon in which the first sub-redistribution pattern 131 is separated from the first encapsulation layer 120 is reduced, and thus, an electrical short circuit phenomenon and the like may be prevented, thereby improving the performance of the semiconductor package 10.

In addition, according to exemplary embodiments of the present invention, the first sub-redistribution pattern 131 is formed with a constant thickness in the second portion except for the portion disposed in the through hole 120H. Thus, while the possibility of a delamination phenomenon may be reduced due to the first portion including the edge 131e formed with a large thickness, process costs may be reduced and the process may be simplified due to the second portion having a constant thickness.

Next, as shown in FIG. 4D, a first insulating pattern 140 and a second sub-redistribution pattern 133 may be sequentially formed on the first sub-redistribution pattern 131. More specifically, after forming the first sub-redistribution pattern 131, in order to form the first insulating pattern 140, an insulating film may be formed on the first encapsulation layer 120 and the first sub-redistribution pattern 131, and portions of the insulating film may be removed so that openings for exposing portions of the first sub-redistribution pattern 131 are formed. After forming the first insulating pattern 140, the second sub-redistribution pattern 133 is formed on the first insulating pattern 140. The second sub-redistribution pattern 133 may be formed to be connected to the first sub-redistribution pattern 131 through the first insulating pattern 140. For example, the second sub-redistribution pattern 133 may be formed through a seed film forming process, a mask process, and an electroplating process.

Thereafter, a protective layer 150 is formed on the first insulating pattern 140. The protective layer 150 may be formed to have openings exposing portions of the second sub-redistribution pattern 133. After forming the protective layer 150, an external connection terminal 190 may be attached onto the second sub-redistribution pattern 133 exposed by the openings of the protective layer 150. The external connection terminal 190 may be, for example, a solder ball or bump.

Referring to FIG. 4E, the carrier 11 (see FIG. 4D) is removed, and the semiconductor packages are singulated into individual semiconductor packages through a sawing process. That is, the semiconductor package illustrated in FIG. 4D may be cut off along a scribe lane SL (see FIG. 4D) and may be separated into a plurality of individual semiconductor packages.

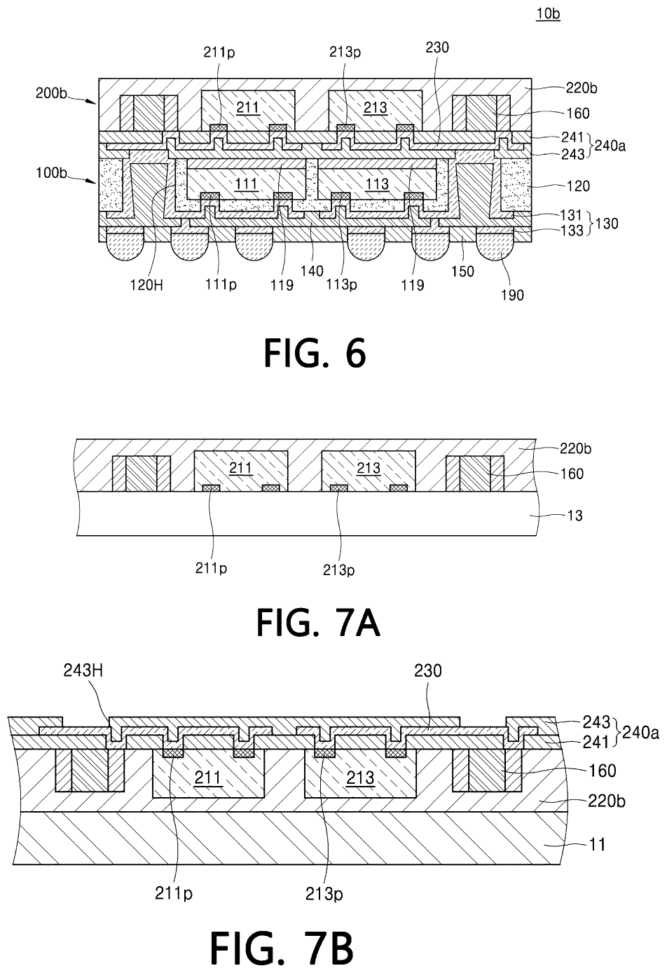

FIG. 5 is a cross-sectional view illustrating a semiconductor package 10a according to exemplary embodiments of the present invention. The semiconductor package 10a illustrated in FIG. 5 may have substantially the same components as the semiconductor package 10 illustrated in FIG. 1, except for a first insulating pattern 140a and a first encapsulation layer 120a that are included in a first package 100a, and a second insulating pattern 240a and a second encapsulation layer 220a that are included in a second package 200a. In FIG. 5, the same descriptions as those described above will be omitted or simply given.

Referring to FIG. 5, the first package 100a may include the first encapsulation layer 120a covering a sidewall of a first semiconductor chip 110. In this case, a lower surface of the first encapsulation layer 120a may be coplanar with a lower surface of the first semiconductor chip 110.

The first encapsulation layer 120a may include an insulating material. In exemplary embodiments, the first encapsulation layer 120a may include a photosensitive material. For example, the first encapsulation layer 120a may be formed of a polymer material such as polyimide.

The first package 100a may include first redistribution structures 130 and 140a. The first redistribution structures 130 and 140a may include a first redistribution pattern 130 and the first insulating pattern 140a.

The first insulating pattern 140a may include a first sub-insulating pattern 141 and a second sub-insulating pattern 143 that are sequentially stacked on the first semiconductor chip 110 and the first encapsulation layer 120a. The first sub-insulating pattern 141 is provided on the lower surface of the first semiconductor chip 110 and the lower surface of the first encapsulation layer 120a, and may have openings for exposing pads 110p of the first semiconductor chip 110. The second sub-insulating pattern 143 may be provided on the first sub-insulating pattern 141 and may cover a first sub-redistribution pattern 131 on the first sub-insulating pattern 141.

In exemplary embodiments, the first insulating pattern 140a may include a photosensitive material. For example, the first insulating pattern 140A may be formed of a polymer material such as polyimide. In addition, in exemplary embodiments, the first insulating pattern 140a may be formed of a dielectric material having a low dielectric constant (low-k), a low thermal expansion coefficient (low-CTE), and/or a low cure temperature.

The first redistribution pattern 130 may include the first sub-redistribution pattern 131 and a second sub-redistribution pattern 133. The first sub-redistribution pattern 131 may extend along the first sub-insulating pattern 141 and may be connected to the pads 110p of the first semiconductor chip 110 through the openings of the first sub-insulating pattern 141. In addition, portions of the first sub-redistribution pattern 131 may be connected to the second redistribution pattern 230 through the first sub-insulating pattern 141, the first encapsulation layer 120a, and a second sub-insulating pattern 243.

Even in the exemplary embodiment of the present invention described with reference to FIG. 5, a thickness of a first portion of the first sub-redistribution pattern 131 may have a size that is not constant in a direction in which through holes 120H extend. In addition, a thickness of a second portion of the first sub-redistribution pattern 131 may have a constant size.

The second package 200a may include the second encapsulation layer 220a covering a sidewall of a second semiconductor chip 210a. In this case, a lower surface of the second encapsulation layer 220a may be coplanar with a lower surface of the second semiconductor chip 210. In exemplary embodiments, the second encapsulation layer 220a may be formed of an EMC, but the present invention is not limited thereto.

The second package 200a may include second redistribution structures 230 and 240a. The second redistribution structures 230 and 240a may include a second redistribution pattern 230 and the second insulating pattern 240a.

The second insulating pattern 240a may include a first sub-insulating pattern 241 and the second sub-insulating pattern 243 that are sequentially stacked on the second semiconductor chip 210a and the second encapsulation layer 220a. The first sub-insulating pattern 241 may be provided on a lower surface of the second semiconductor chip 210a and the lower surface of the second encapsulation layer 220a, and may have openings for exposing pads 210p of the second semiconductor chip 210a. The second sub-insulating pattern 243 may be provided on the first sub-insulating pattern 241 and may cover the second redistribution pattern 230 on the first sub-insulating pattern 241.

In exemplary embodiments, the second insulating pattern 240a may include a photosensitive material. For example, the second insulating pattern 240a may be formed of a polymer material such as polyimide. In addition, in exemplary embodiments, the second insulating pattern 240a may be formed of a dielectric material having characteristics of a low dielectric constant, a low thermal expansion coefficient, and/or a low curing temperature.

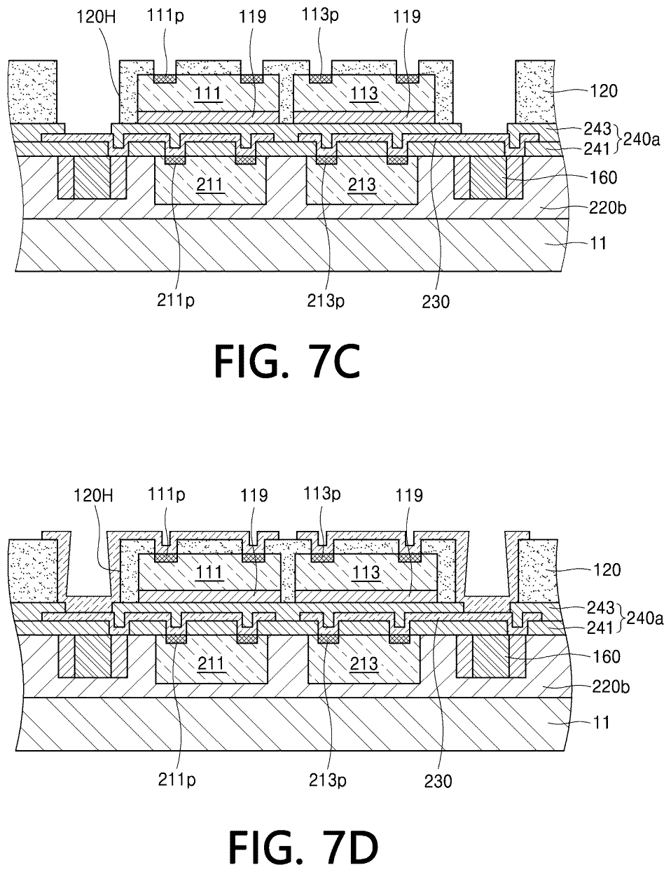

FIG. 6 is a cross-sectional view illustrating a semiconductor package 10b according to exemplary embodiments of the present invention. In FIG. 6, the same descriptions as those described above will be omitted or simply given.

Referring to FIG. 6, the semiconductor package 10b may include a first package 100b and a second package 200b. The semiconductor package 10b may be, for example, a PoP-type semiconductor package in which the second package 200b is attached onto the first package 100b. The first package 100b may be, for example, a FOWLP-type semiconductor package.

The first package 100b may include a plurality of semiconductor chips 111 and 113. For example, the first package 100b may include a first lower semiconductor chip 111 and a second lower semiconductor chip 113 that are horizontally spaced apart from each other. In exemplary embodiments, the first lower semiconductor chip 111 and the second lower semiconductor chip 113 may be the same kind of semiconductor chips. Alternatively, in exemplary embodiments, the first lower semiconductor chip 111 and the second lower semiconductor chip 113 may be different kinds of semiconductor chips.

The first package 100b may include a first encapsulation layer 120 that covers at least a portion of the first lower semiconductor chip 111 and at least a portion of the second lower semiconductor chip 113. The first encapsulation layer 120 may include an insulating material. In exemplary embodiments, the first encapsulation layer 120 may be formed of a photosensitive material, for example, a polymer material such as polyimide.

The second package 200b may include a plurality of semiconductor chips 211 and 213. For example, the second package 200b may include a first upper semiconductor chip 211 and a second upper semiconductor chip 213 that are horizontally spaced apart from each other. In exemplary embodiments, the first upper semiconductor chip 211 and the second upper semiconductor chip 213 may be the same kind of semiconductor chips. Alternatively, in exemplary embodiments, the first upper semiconductor chip 211 and the second upper semiconductor chip 213 may be different kinds of semiconductor chips.

Furthermore, in exemplary embodiments, the second package 200b may be an SIP-type semiconductor package in which various circuit devices that perform a signal processing function, for example, a passive device 160 and the like, are packaged.

The second package 200b may include a second encapsulation layer 220b that covers at least a portion of the first upper semiconductor chip 211 and at least a portion of the second upper semiconductor chip 213. The second encapsulation layer 220b may be filled between the first upper semiconductor chip 211 and the second upper semiconductor chip 213. In exemplary embodiments, the second encapsulation layer 220b may be formed of an EMC, but the present invention is not limited thereto.

Even in the exemplary embodiment of the present invention described with reference to FIG. 6, a thickness of a first portion of the first sub-redistribution pattern 131 may have a size that is not constant in a direction in which through holes 120H extend. In addition, a thickness of a second portion of the first sub-redistribution pattern 131 may have a constant size.

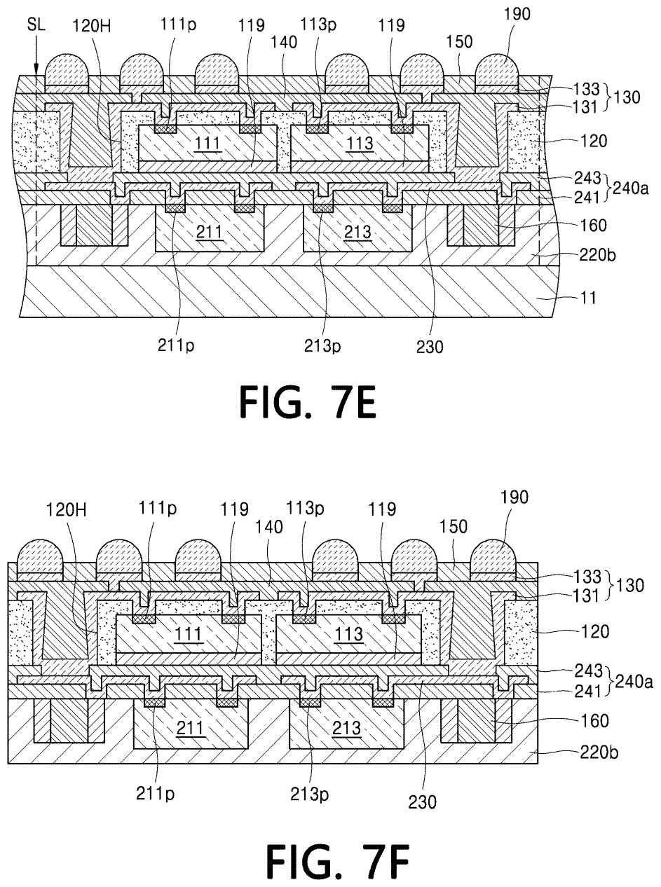

FIGS. 7A to 7F are cross-sectional views illustrating a method of manufacturing the semiconductor package according to exemplary embodiments of the present invention. In FIGS. 7A to 7F, a method of manufacturing the semiconductor package 10b illustrated in FIG. 6 will be described.

Referring to FIG. 7A, a first upper semiconductor chip 211 and a second upper semiconductor chip 213 are disposed on a support substrate 13. Subsequently, a second encapsulation layer 220b that covers the first upper semiconductor chip 211 and the second upper semiconductor chip 213 is formed on the support substrate 13. In exemplary embodiments, the second encapsulation layer 220b may include an EMC. Alternatively, in exemplary embodiments, the second encapsulation layer 220b may include an insulating film including a photosensitive material, as in the second encapsulation layer 220 of FIG. 4A.

Referring to FIG. 7B, the support substrate 13 is removed from the resultant structure of FIG. 7A, and the resultant structure is turned upside down and disposed on a carrier 11.

Thereafter, second redistribution structures 230 and 240a are formed on the second encapsulation layer 220b, the first upper semiconductor chip 211, and the second upper semiconductor chip 213. In order to form the second redistribution structures 230 and 240a, a first sub-insulating pattern 241, a second redistribution pattern 230, and a second sub-insulating pattern 243 may be sequentially formed. More specifically, in the first sub-insulating pattern 241, an insulating film is formed on the first upper semiconductor chip 211 and the second upper semiconductor chip 213, and portions of the insulating film is removed so that openings for exposing pads 211p of the first upper semiconductor chip 211 and pads 213p of the second upper semiconductor chip 213 may be formed. After forming the first sub-insulating pattern 241, the second redistribution pattern 230 may be formed on the first sub-insulating pattern 241. For example, the second redistribution pattern 230 may be formed through a seed film forming process, a mask process, and an electroplating process. After forming the second redistribution pattern 230, the second sub-insulating pattern 243 that covers the second redistribution pattern 230 may be formed on the first sub-insulating pattern 241. The second sub-insulating pattern 243 may be formed to have openings 243H for exposing portions of the second redistribution pattern 230.

Referring to FIG. 7C, a first lower semiconductor chip 111 and a second lower semiconductor chip 113 are disposed on the second sub-insulating pattern 243. An adhesive layer 119 for fixing the first lower semiconductor chip 111 and the second lower semiconductor chip 113 may be provided between the first lower semiconductor chip 111 and the second insulating pattern 240a and between the second lower semiconductor chip 113 and the second sub-insulating pattern 243.

After forming the first lower semiconductor chip 111 and the second lower semiconductor chip 113, a first encapsulation layer 120 that covers the first lower semiconductor chip 111 and the second lower semiconductor chip 113 may be formed. The first encapsulation layer 120 may be formed to have through holes 120H vertically passing through the first encapsulation layer 120, and openings that expose pads 111p of the first lower semiconductor chip 111 and pads 113p of the second lower semiconductor chip 113 by a method similar to that described in FIG. 4B.

Referring to FIGS. 7D and 7E, first redistribution structures 130 and 140 may be formed on the first encapsulation layer 120, the first lower semiconductor chip 111, and the second lower semiconductor chip 113. Specifically, first, as shown in FIG. 7D, in order to form the first redistribution structures 130 and 140, a first sub-redistribution pattern 131 may be formed by a method similar to that described with reference to FIG. 4C. Thereafter, referring to FIG. 7E, a first insulating pattern 140 and a second sub-redistribution pattern 133 may be sequentially formed on the first sub-redistribution pattern 131. Thereafter, by a method similar to the method described in FIG. 4D, a protective layer 150 may be formed on the first insulating pattern 140, and external connection terminals 190 attached onto the protective layer 150 may be formed.

Referring to FIG. 7F, the carrier 11 (see FIG. 7E) is removed and the semiconductor package illustrated in FIG. 7E is cut off along a scribe lane SL (see FIG. 7E) so that the semiconductor package of FIG. 7E may be singulated into a plurality of individual semiconductor packages.

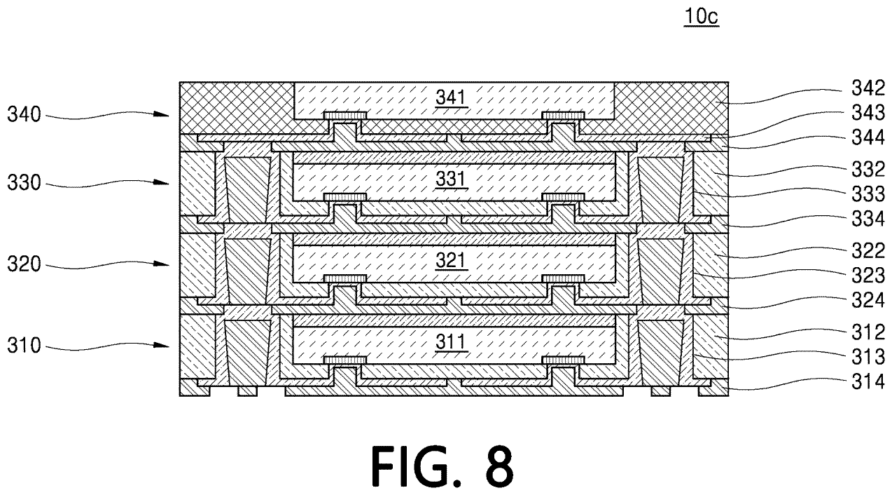

FIG. 8 is a cross-sectional view illustrating a semiconductor package 10c according to exemplary embodiments of the present invention. In FIG. 8, the same descriptions as those described above will be omitted or simply given.

Referring to FIG. 8, a semiconductor package 10c may include a first package 310, a second package 320, a third package 330, and a fourth package 340 that are stacked in a vertical direction. Each of the first package 310, the second package 320, the third package 330, and the fourth package 340 may be a FOWLP-type semiconductor package.

The first package 310 may include a first semiconductor chip 311, a first encapsulation layer 312, and first redistribution structures 313 and 314. The second package 320 may include a second semiconductor chip 321, a second encapsulation layer 322, and second redistribution structures 323 and 324. The third package 330 may include a third semiconductor chip 331, a third encapsulation layer 332, and third redistribution structures 333 and 334. For example, the first package 310, the second package 320, and the third package 330 may have technical features similar to those of the first package 100 (see FIG. 1) described above with reference to FIG. 1, and thus detailed descriptions thereof will be omitted.

The fourth package 340 may include a fourth semiconductor chip 341, a fourth encapsulation layer 342, and fourth redistribution structures 343 and 344. For example, the fourth package 340 may have a technical feature similar to that of the second package 200 (see FIG. 1) described above with reference to FIG. 1, and thus a detailed description thereof will be omitted.

The first semiconductor chip 311 of the first package 310, the second semiconductor chip 321 of the second package 320, the third semiconductor chip 331 of the third package 330, and the fourth semiconductor chip 341 of the fourth package 340 may be the same kind of semiconductor chips or different kinds of semiconductor chips.

In exemplary embodiments of the present invention, an electrical connection between the first to fourth semiconductor chips 311, 321, 323, and 324 may be implemented through a first redistribution pattern 313 of the first package 310 that extends through the first encapsulation layer 312 and a second insulating pattern 324, a second redistribution pattern 323 of the second package 320 that extends through the second encapsulation layer 322 and a third insulating pattern 334, a third redistribution pattern 333 of the third package 330 that extends through the third encapsulation layer 332 and a fourth insulating pattern 344, and a fourth redistribution pattern 343 of the fourth package 340. The first to fourth packages 310, 320, 330, and 340 may be electrically connected without inter-package connection terminals vulnerable to warpage, so that the reliability of the semiconductor package 10c may be improved. In addition, the plurality of packages can be stacked without the inter-package connection terminals, so that the thinner semiconductor package 10c may be manufactured.

Even in the exemplary embodiment of the present invention described with reference to FIG. 8, a thickness of a first portion of each of the redistribution patterns 313, 323, and 333 may have a size that is not constant in a direction in which through holes 120H extend. In addition, a thickness of a second portion of each of the redistribution patterns 313, 323, and 333 may have a constant size.

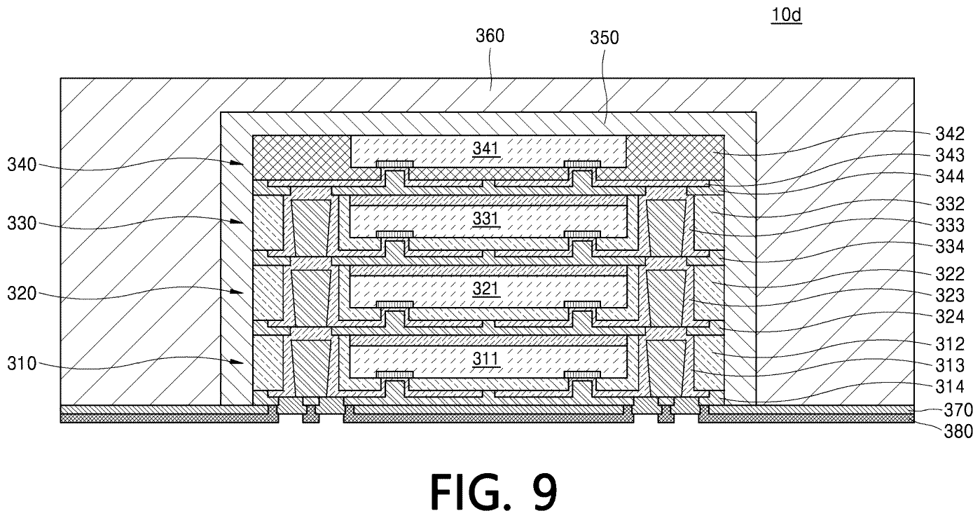

FIG. 9 is a cross-sectional view illustrating a semiconductor package 10d according to exemplary embodiments of the present invention. In FIG. 9, the same descriptions as those described above will be omitted or simply given.

Referring to FIG. 9, the semiconductor package 10d may include a first package 310, a second package 320, a third package 330, and a fourth package 340 that are stacked in a vertical direction. For example, the first to fourth packages 310, 320, 330, and 340 may have technical features similar to those of the semiconductor package 10c described with reference to FIG. 8, and thus detailed descriptions thereof will be omitted.

The semiconductor package 10d may include an electromagnetic shielding layer 350 that covers at least portions of the first package 310, the second package 320, the third package 330, and the fourth package 340. For example, as illustrated in the drawing, the electromagnetic shielding layer 350 may cover a sidewall of the first package 310, a sidewall of the second package 320, a sidewall of the third package 330, and a sidewall and an upper surface of the fourth package 340. The electromagnetic shielding layer 350 shields electromagnetic interference (EMI) and may prevent performance degradation of the semiconductor package 10d due to EMI.

For example, in order to form the electromagnetic shielding layer 350, a conductive material film that covers the first to fourth packages 310, 320, 330, and 340 may be formed by using a method such as chemical vapor deposition (CVD), electroless plating, electrolytic plating, spraying, sputtering, or the like. The electromagnetic shielding layer 350 may include a conductive material such as copper (Cu), silver (Ag), or platinum (Pt).

The semiconductor package 10d may include an outer encapsulation layer 360 that covers the electromagnetic shielding layer 350 covering the first to fourth packages 310, 320, 330, and 340. In exemplary embodiments, the outer encapsulation layer 360 may include a material having high thermal conductivity so that heat dissipation characteristics of the semiconductor package 10d are improved.

The semiconductor package 10d may include a lower conductive layer 370 and a thermal conductive film 380 that are provided on a lower surface of the first package 310 and a lower surface of the outer encapsulation layer 360.

The lower conductive layer 370 may extend from a surface of a first insulating pattern 314 of the first package 310, a surface of the outer encapsulation layer 360, and/or a surface of the electromagnetic shielding layer 350 between the first package 310 and the outer encapsulation layer 360.

A portion of the lower conductive layer 370 extends along the first insulating pattern 314, and may be connected to the first redistribution pattern 313 of the first package 310 through openings of the first insulating pattern 314.

In addition, a portion of the lower conductive layer 370 is connected to the electromagnetic shielding layer 350, and may function as an electrical path for grounding an electromagnetic wave incident on the electromagnetic shielding layer 350.

For example, the lower conductive layer 370 may include a conductive material. For example, the lower conductive layer 370 may include a material having low resistivity, for example, copper (Cu).

The thermal conductive film 380 may be provided on the surface of the first insulating pattern 314 of the first package 310, the surface of the outer encapsulation layer 360, and/or the surface of the electromagnetic shielding layer 350 between the first package 310 and the outer encapsulation layer 360. The thermal conductive film 380 covers the lower conductive layer 370, and may include openings exposing portions of the lower conductive layer 370.

For example, the thermal conductive film 380 may include an insulating material having high thermal conductivity.

Even in the exemplary embodiment of the present invention described with reference to FIG. 9, a thickness of a first portion of each of the redistribution patterns 313, 323, and 333 may have a size that is not constant in a direction in which through holes 120H extend. In addition, a thickness of a second portion of each of the redistribution patterns 313, 323, and 333 may have a constant size.

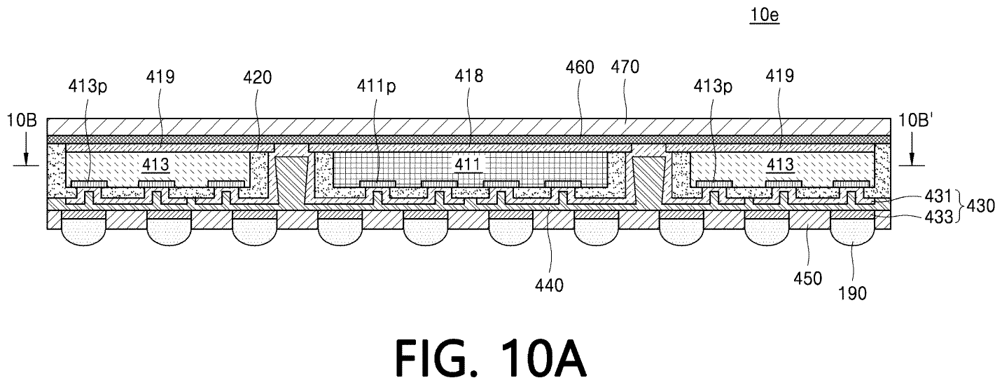

FIG. 10A is a cross-sectional view illustrating a semiconductor package 10e according to exemplary embodiments of the present invention. FIG. 10B is a cross-sectional view illustrating the semiconductor package 10e taken along line 10B-10B′ of FIG. 10A.

Referring to FIGS. 10A and 10B, the semiconductor package 10e may include a semiconductor chip 411 and passive parts 413. The semiconductor package 10e may be a SIP-type semiconductor package in which the semiconductor chip 411 and the passive parts 413 are packaged by a fan-out method.

In exemplary embodiments, the semiconductor chip 411 may be a logic chip. For example, the semiconductor chip 411 may be an AI processor. Alternatively, the semiconductor chip 411 may be a CPU, an MPU, a GPU, or an AP. Alternatively, in exemplary embodiments, the semiconductor chip 411 may be a memory semiconductor chip.

In exemplary embodiments, the passive part 413 may include an integrated passive device (IPD). The IPD may include, for example, various types of passive devices provided on a silicon substrate.

In exemplary embodiments, the passive parts 413 may include various types of passive devices formed on a substrate having a cavity that may accommodate the semiconductor chip 411. For example, as illustrated in FIG. 10B, the passive part 413 may have a ring shape surrounding the semiconductor chip 411.

Alternatively, in other exemplary embodiments, the semiconductor package 10e may include a plurality of passive parts 413 spaced apart from each other.

The semiconductor package 10e may include an encapsulation layer 420 that molds the semiconductor chip 411 and the passive parts 413 so that the semiconductor chip 411 and the passive parts 413 are integrated with each other. The encapsulation layer 420 may cover at least a portion of the semiconductor chip 411 and at least a portion of the passive part 413. For example, the encapsulation layer 420 may cover a sidewall of the semiconductor chip 411 and a lower surface of the semiconductor chip 411 on which pads 411p of the semiconductor chip 411 are provided, and may cover a sidewall of the passive parts 413 and a lower surface of the passive parts 413 on which pads 413p of the passive parts 413 are provided.

The semiconductor package 10e may include redistribution structures 430 and 440. The redistribution structures may include a redistribution pattern 430 and an insulating pattern 440.

The redistribution pattern 430 may electrically connect the pads 411p of the semiconductor chip 411 to external connection terminals 190 and may electrically connect the pads 413p of the passive parts 413 to the external connection terminals 190. The redistribution pattern 430 may be formed of a plurality of sub-redistribution patterns 430, and the sub-redistribution patterns 430 may have a multilayer structure. For example, the redistribution pattern 430 may include a first sub-redistribution pattern 431 and second sub-redistribution pattern 433. The first sub-redistribution pattern 431 may extend along a surface of the encapsulation layer 420, may be connected to the pads 411p of the semiconductor chip 411, and may be connected to the pads 413p of the passive parts 413. In addition, a portion of the first sub-redistribution pattern 431 may extend in a vertical direction through the encapsulation layer 420.

The insulating pattern 440 is provided on a lower surface of the encapsulation layer 420 and may cover at least a portion of the first sub-redistribution pattern 431.

A protective layer 450 may be formed on the insulating pattern 440. The protective layer 450 covers the second sub-redistribution pattern 433, and may expose a portion of the second sub-redistribution pattern 433. The external connection terminal 190 may be disposed in the portion of the second sub-redistribution pattern 433, which is exposed by the protective layer 450.

A thermal conductive film 460 and a heat dissipation plate 470 may be provided on an upper surface of the semiconductor chip 411 and an upper surface of the passive part 413. An adhesive layer 418 for fixing the semiconductor chip 411 may be provided between the upper surface of the semiconductor chip 411 and the thermal conductive film 460, and an adhesive layer 419 for fixing the passive parts may be provided between the upper surfaces of the passive parts 413 and the thermal conductive film 460. In exemplary embodiments, the adhesive layers 418 and 419 may include a material having high thermal conductivity so that heat dissipation characteristics of the semiconductor chip 411 and heat dissipation characteristics of the passive parts 413 are improved.

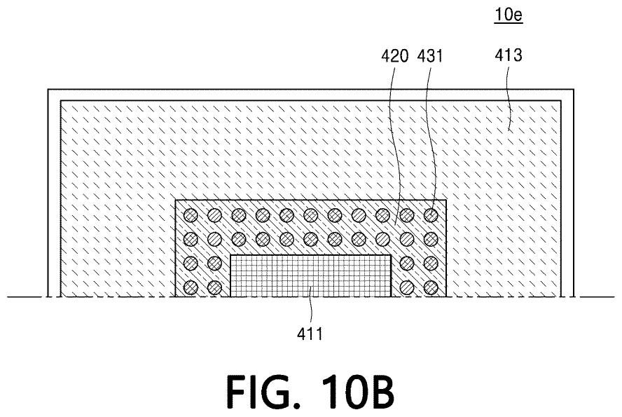

FIG. 11 is a cross-sectional view illustrating a semiconductor package 10f according to exemplary embodiments of the present invention. In FIG. 11, the same descriptions as those described above will be omitted or simply given.

Referring to FIG. 11, the semiconductor package 10f may include a lower package 610 and an upper package 620. The lower package 610 may have the same components as the semiconductor package 10e illustrated in FIGS. 10A and 10B and the upper package 620 may have the same components as the semiconductor package 10d illustrated in FIG. 9, and thus, detailed descriptions of the lower package 610 and the upper package 620 will be omitted.

As shown in FIG. 11, a first sub-redistribution pattern 431 provided in the lower package 610 may extend through an encapsulation layer 420 and a thermal conductive film 380 of the lower package 610 and may be connected to a lower conductive layer 370. That is, a semiconductor chip 411 of the lower package 610 and first to fourth semiconductor chips 311, 321, 331, and 341 of the upper package 620 may be connected through a redistribution pattern 430 of the lower package 610, the lower conductive layer 370 of the upper package 620, and first to fourth redistribution pattern 313, 323, 333, and 343 of the upper package 620.

In exemplary embodiments, the semiconductor chip 411 of the lower package 610 may be an AI processor, and the first to fourth semiconductor chips 311, 321, 331, and 341 of the upper package 620 may be memory semiconductor chips configured to transmit and receive an electrical signal to and from the semiconductor chip 411 of the lower package 610.

In exemplary embodiments of the present invention, the lower package 610 and the upper package 620 may be electrically connected to each other without inter-package connection terminals vulnerable to warpage, so that the reliability of the semiconductor package 10f may be improved. In addition, a plurality of packages can be stacked without the inter-package connection terminals, so that the thinner semiconductor package 10f may be manufactured.

Hereinafter, a semiconductor package according to another embodiment of the present invention will be described with reference to the accompanying drawings.

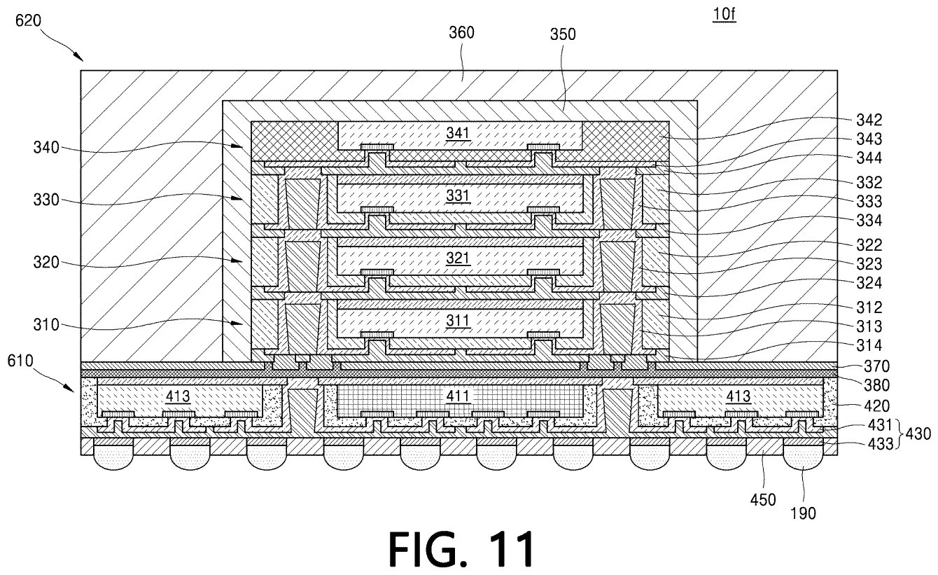

FIG. 12 is a cross-sectional view illustrating a semiconductor package according to exemplary embodiments of the present invention.

Referring to FIG. 12, a semiconductor package 10 may include a first package 100 and a second package 200.

The semiconductor package 10 may be, for example, a PoP-type semiconductor package in which the second package 200 is attached onto the first package 100. In addition, the semiconductor package 10 may also be, for example, a 3D stacked semiconductor package, or an SIP-type semiconductor package in which each layer having various functions is stacked, or connected side by side.

The first package 100 may be, for example, a FOWLP-type semiconductor package.

The first package 100 may include a first semiconductor chip 110. A semiconductor substrate forming the first semiconductor chip 110 may include, for example, silicon (Si). Alternatively, the semiconductor substrate forming the first semiconductor chip 110 may include a semiconductor element such as germanium (Ge), or a compound semiconductor such as silicon carbide (SiC), gallium arsenide (GaAs), indium arsenide (InAs), and indium phosphide (InP). Alternatively, the semiconductor substrate forming the first semiconductor chip 110 may have an SOI structure.

The semiconductor substrate forming the first semiconductor chip 110 may have an active surface and an inactive surface opposite the active surface. The first semiconductor chip 110 may be manufactured by forming a semiconductor device including a plurality of various types of individual devices on the active surface. The plurality of individual devices may include various microelectronic devices, for example, a MOSFET, such as a CMOS, an image sensor, such as an LSI, a CIS, a MEMS, an active device, a passive device, and the like.

The first semiconductor chip 110 may include a plurality of pads 110p. The plurality of pads 110p may be electrically connected to the semiconductor device included in the first semiconductor chip 110. The first semiconductor chip 110 may be a single semiconductor chip, but embodiments are not limited thereto. For example, the first semiconductor chip 110 may be a stack of a plurality of semiconductor chips.

In exemplary embodiments, the first semiconductor chip 110 may be, for example, a memory semiconductor chip. The memory semiconductor chip may be, for example, a volatile memory semiconductor chip, such as a DRAM or a SRAM, or a nonvolatile memory semiconductor chip, such as a PRAM, a MRAM, a FeRAM or a RRAM.

Alternatively, in other exemplary embodiments, the first semiconductor chip 110 may be a logic chip. For example, the first semiconductor chip 110 may be an AI processor, a CPU, an MPU, a GPU, or an AP.

The first package 100 may include a first encapsulation layer 120 covering at least a portion of the first semiconductor chip 110. The first encapsulation layer 120 covers a side surface of the first semiconductor chip 110, and may cover a lower surface of the first semiconductor chip 110, on which the pads 110p are provided. The first encapsulation layer 120 may have openings for exposing the pads 110p of the first semiconductor chip 110.

The first encapsulation layer 120 may include an insulating material. In exemplary embodiments, the first encapsulation layer 120 may include a photosensitive material. For example, the first encapsulation layer 120 may include a polymer material such as polyimide. However, the material of the first encapsulation layer 120 is not limited thereto, and for example, the first encapsulation layer 120 may include an EMC.

The first encapsulation layer 120 may include through holes 120H each vertically passing through one side surface and the other side surface of the first encapsulation layer 120. One side surface of the first encapsulation layer 120 is a surface facing the second package 200 in FIG. 12, and the other side surface of the first encapsulation layer 120 is a surface opposite to the one side surface facing the second package 200 in FIG. 12. For example, the through hole 120H may be formed to vertically pass through the first encapsulation layer 120. The through holes 120H may be provided in a peripheral portion of the first semiconductor chip 110.

The first package 100 may include first redistribution structures 130 and 140d provided on the first semiconductor chip 110. The first redistribution structures 130 and 140d may include a first redistribution pattern 130 and a first insulating pattern 140d.

The first redistribution pattern 130 is connected to the pads 110p of the first semiconductor chip 110. The first redistribution pattern 130 may electrically connect the pads 110p of the first semiconductor chip 110 to external connection terminals 190.

In addition, the first redistribution pattern 130 may be electrically connected to a second redistribution pattern 230. Through the first redistribution pattern 130 and the second redistribution pattern 230, the first semiconductor chip 110 may be electrically connected to a second semiconductor chip 210, and thus, the second semiconductor chip 210 may be electrically connected to the external connection terminals 190.

The first redistribution pattern 130 may include a plurality of sub-redistribution patterns, and the sub-redistribution patterns may have a multilayer structure. For example, the first redistribution pattern 130 may include a first sub-redistribution pattern 131 and a second sub-redistribution pattern 133.

The first sub-redistribution pattern 131 is formed on the first encapsulation layer 120, and may be connected to the pad 110p of the first semiconductor chip 110. The first sub-redistribution pattern 131 may include a first conductive layer 131a and a second conductive layer 131b.

The first conductive layer 131a, which is a portion of the first sub-redistribution pattern 131, may be connected to the second redistribution pattern 230 through the first encapsulation layer 120 and a second insulating pattern 240.

The first conductive layer 131a is disposed on an inner surface of the through hole 120H of the first encapsulation layer 120 and is connected to the second package 200.

The second conductive layer 131b is disposed on the other side surface of the first encapsulation layer 120. One side of the second conductive layer 131b is connected to the first conductive layer 131a and the other side thereof is connected to the pads 110p of the first semiconductor chip 110.

The first conductive layer 131a may include a first seed layer 131as and a first plating layer 131ap that are sequentially disposed on the inner surface of the through hole 120H. A space inside the through hole 120H, in which the first seed layer 131as and the first plating layer 131ap are disposed, is filled with a filling portion 140 made of an insulating material such as a resin. Here, the filling portion 140 of FIG. 12 has similar technical features to a portion of the first insulating pattern 140 of the semiconductor package illustrated in FIG. 1, and thus, is indicated by the same reference numeral.

The first plating layer 131ap may be formed to be thicker than the first seed layer 131as. The first plating layer 131ap may be formed on a surface of the first seed layer 131as by electroplating or electroless plating.

The second conductive layer 131b may include a second seed layer 131bs and a second plating layer 131bp that are sequentially disposed on the other side surface of the first encapsulation layer 120. The second plating layer 131bp may be formed to be thicker than the second seed layer 131bs. The second plating layer 131bp may be formed on a surface of the second seed layer 131bs by electroplating or electroless plating.

The first insulating pattern 140d may be provided on a lower surface of the first encapsulation layer 120. The first insulating pattern 140d covers the first sub-redistribution pattern 131, and may have openings that expose portions of the first sub-redistribution pattern 131.

The second sub-redistribution pattern 133 may extend on the first insulating pattern 140d and may be connected to the first sub-redistribution pattern 131 through the first insulating pattern 140d.

A protective layer 150 may be formed on the first insulating pattern 140d. The protective layer 150 may expose a portion of the second sub-redistribution pattern 133. The external connection terminal 190 may be disposed in the portion of the second sub-redistribution pattern 133 exposed by the protective layer 150. The external connection terminal 190 may be, for example, a solder ball or bump. The external connection terminals 190 may electrically connect between the semiconductor package 10 and an external device.

The second package 200 may be disposed on the first package 100. The second package 200 may include the second semiconductor chip 210. The second semiconductor chip 210 may include pads 210p. The second semiconductor chip 210 may be a single semiconductor chip, but embodiments are not limited thereto. For example, the second semiconductor chip 210 may be a stack of a plurality of semiconductor chips.

In exemplary embodiments, the second semiconductor chip 210 may be, for example, a memory semiconductor chip. Alternatively, in exemplary embodiments, the second semiconductor chip 210 may be a logic chip.

The second package 200 may include a second encapsulation layer 220 covering at least a portion of the second semiconductor chip 210. For example, the second encapsulation layer 220 covers a side surface of the second semiconductor chip 210, and may cover a lower surface of the second semiconductor chip 210 on which the pads 210p are formed. The second encapsulation layer 220 may have openings for exposing the pads 210p of the second semiconductor chip 210. In this case, the second encapsulation layer 220 may not cover an upper surface of the second semiconductor chip 210 opposite to the lower surface of the second semiconductor chip 210.

The second encapsulation layer 220 may include an insulating material. In exemplary embodiments, the second encapsulation layer 220 may include a photosensitive material. For example, the second encapsulation layer 220 may include a polymer material such as polyimide. However, the material forming the second encapsulation layer 220 is not limited the polymer material, and for example, the second encapsulation layer 220 may include an EMC.

The second package 200 may include second redistribution structures 230 and 240 provided between the second encapsulation layer 220 and the first encapsulation layer 120. The second redistribution structures 230 and 240 may include the second redistribution pattern 230 and the second insulating pattern 240. The second redistribution pattern 230 may extend along a surface of the second encapsulation layer 220 and may be electrically connected to the pads 210p of the second semiconductor chip 210.

An adhesive layer 119 for fixing the first semiconductor chip 110 and the second package 200 may be provided between the first semiconductor chip 110 and the second insulating pattern 240. The adhesive layer 119 may include, for example, a die attach film. In addition, the adhesive layer 119 may include a material having high thermal conductivity so that heat of the first semiconductor chip 110 may be effectively emitted.

In the semiconductor package 10 according to one embodiment, an electrical connection between the second package 200 and the first package 100 may be made through a connection between the first redistribution pattern 130 and the second redistribution pattern 230. Specifically, since the first conductive layer 131a is directly connected to the second redistribution pattern 230 through the through holes 120H, the pads 210p of the second semiconductor chip 210 are electrically connected to the first redistribution pattern 130.

The structure of the semiconductor package 10 of the embodiments is not limited by the electrical connection structure between the pads 210p of the second semiconductor chip 210 and the first redistribution pattern 130 illustrated in FIG. 12. For example, the first conductive layer 131a may be directly connected to the pads 210p of the second semiconductor chip 210 through the through holes 120H.

The semiconductor package 10 according to the above-described embodiment does not include inter-package connection terminals such as solder balls for connecting the second package 200 and the first package 100, and thus, semiconductor package manufacturing processes may be simplified and a thinner PoP-type semiconductor package may be manufactured.

In general, in the case of a PoP-type semiconductor package in which a plurality of packages are stacked, due to warpage of the semiconductor package, damage such as cracks occurs in the inter-package connection terminals, which may reduce the reliability of the semiconductor package. However, according to exemplary embodiments, since the second package 200 and the first package 100 may be electrically connected without the inter-package connection terminals vulnerable to warpage, the reliability of the semiconductor package 10 may be improved.

In the semiconductor package 10 according to the above-described embodiment, the first sub-redistribution pattern 131 includes the first conductive layer 131a disposed in the through hole 120H, and the second conductive layer 131b that is distinct from the first conductive layer 131a and disposed on the other side surface of the first encapsulation layer 120. That is, since the first conductive layer 131a, which is disposed along the through holes 120H for electrical connection of the first package 100 and the second package 200, and the second conductive layer 131b for electrical connection of the first conductive layer 131a and the first semiconductor chip 110 of the first package 100 are formed independently of each other, the reliability of the overall electrical connection structure of the semiconductor package 10 may be improved.

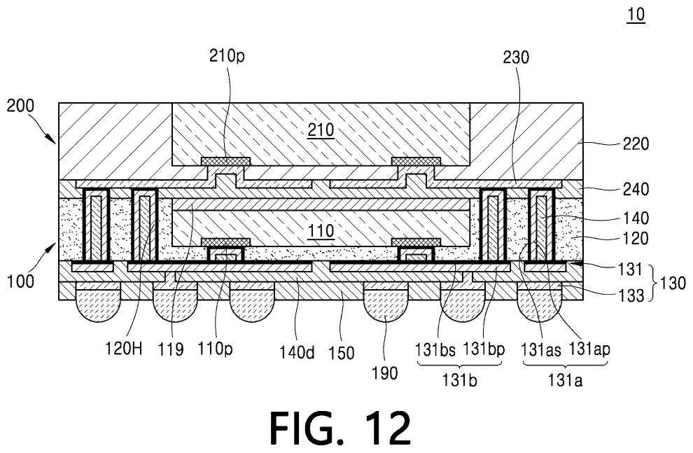

FIG. 13 is a flowchart illustrating operations of a method of manufacturing the semiconductor package according to exemplary embodiments of the present invention.

The method of manufacturing the semiconductor package according to embodiments illustrated in FIG. 13 includes operation S100 of preparing a base package, operation S110 of mounting a semiconductor chip on the base package, operation S120 of disposing an encapsulation layer so as to cover the semiconductor chip, operation S130 of forming through holes passing through one side surface and the other side surface of the encapsulation layer, and operation S140 of forming a first conductive layer so as to cover inner surfaces of the through holes and the other side surface of the encapsulation layer, operation S141 of forming an insulating layer so as to fill the through holes and cover the first conductive layer, a surface planarization operation S150 of removing a portion of the first conductive layer covering the insulating layer and the other side surface of the encapsulation layer, and operation S160 of forming a second conductive layer on the other side surface of the encapsulation layer, from which the first conductive layer is removed, to connect pads of the semiconductor chip to the first conductive layer disposed on the inner surface of the through hole.

Operation S140 of forming the first conductive layer includes, for example, an operation of forming a first seed layer on the inner surface of the through hole, and a first plating operation of forming a first plating layer on a surface of the first seed layer by electroplating or electroless plating.

Operation S160 of forming the second conductive layer includes, for example, an operation of forming a second seed layer on the other side surface of the encapsulation layer from which the first conductive layer is removed, and a second plating operation of forming a second plating layer on a surface of the second seed layer by electroplating or electroless plating.

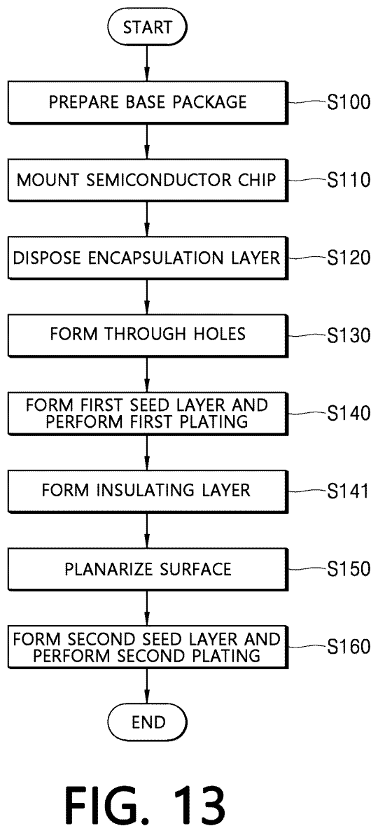

FIGS. 14 to 25 are cross-sectional views illustrating the method of manufacturing the semiconductor package according to exemplary embodiments of the present invention. Hereinafter, a specific example of each of the operations of the method of manufacturing the semiconductor package illustrated in FIG. 13 will be described with reference to FIGS. 14 to 25.

FIG. 14 illustrates the operation of preparing the base package in the manufacturing method illustrated in FIG. 13.

In the operation of preparing the base package, a second package 200 including a second semiconductor chip 210 is prepared. Thus, the “base package” in the preparing of the base package corresponds to the second package 200 illustrated in FIG. 14.

Referring to FIG. 14, in order to prepare the second package 200, the second semiconductor chip 210 is disposed on a carrier 11, and a second encapsulation layer 220 covering the second semiconductor chip 210 is formed. The second encapsulation layer 220 may be formed to cover a side surface of the second semiconductor chip 210, and a surface of the second semiconductor chip 210 on which pads 210p are provided.

In exemplary embodiments, in order to form the second encapsulation layer 220, an insulating film is coated on the carrier 11 and the second semiconductor chip 210, and portions of the insulating film may be removed so that the pads 210p of the second semiconductor chip 210 are exposed. The insulating film may include, for example, a photosensitive material.

After forming the second encapsulation layer 220, second redistribution structures 230 and 240 may be formed on the second encapsulation layer 220 and the second semiconductor chip 210. Specifically, a second redistribution pattern 230 may be formed on the second encapsulation layer 220 and the pads 210p of the second semiconductor chip 210. For example, the second redistribution pattern 230 may be formed through a seed film forming process, a mask process, and an electroplating process. After forming the second redistribution pattern 230, in order to form a second insulating pattern 240, an insulating film may be formed on the second encapsulation layer 220 and the second redistribution pattern 230 and a portion of the insulating film may be removed so that openings 240H for exposing portions of the second redistribution pattern 230 are formed.

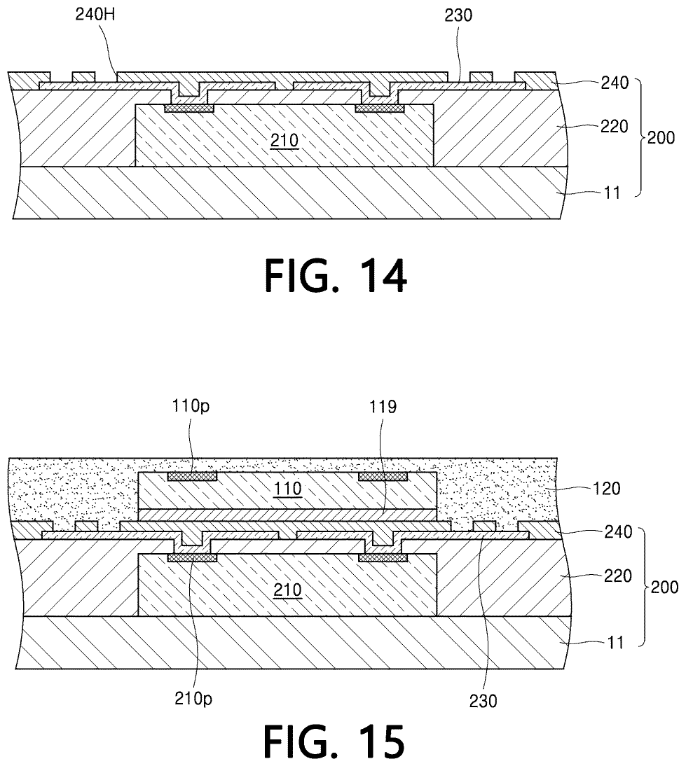

FIG. 15 illustrates the operation of mounting the semiconductor chip and the operation of disposing the encapsulation layer in the manufacturing method illustrated in FIG. 13.

In the operation of mounting the semiconductor chip, the semiconductor chip is mounted on a base package (second package 200). A first semiconductor chip 110 illustrated in FIG. 15 corresponds to the “semiconductor chip” in the operation of mounting the semiconductor chip.

Referring to FIG. 15, the first semiconductor chip 110 is disposed on the second insulating pattern 240. An adhesive layer 119 for fixing the first semiconductor chip 110 may be provided between the first semiconductor chip 110 and the second insulating pattern 240. The adhesive layer 119 may include, for example, a die attach film. In addition, the adhesive layer 119 may include a material having high thermal conductivity so that heat of the first semiconductor chip 110 may be effectively emitted.

After the operation of mounting the semiconductor chip, the operation of disposing the encapsulation layer so as to cover the semiconductor chip is performed. A first encapsulation layer 120 illustrated in FIG. 15 corresponds to the “encapsulation layer” in the operation of disposing the encapsulation layer.

After disposing the first semiconductor chip 110, the first encapsulation layer 120 that covers the first semiconductor chip 110 may be formed.

In exemplary embodiments, the first encapsulation layer 120 is formed by a lamination process using a polymer material such as polyimide and may cover a side surface of the first semiconductor chip 110 and a surface of the first semiconductor chip 110 on which pads 110p are provided. In this case, in comparison with the case in which an operation of forming a mold material that covers the side surface of the first semiconductor chip 110 and an operation of sequentially forming insulating materials on the lower surface of the first semiconductor chip 110 are performed, the first encapsulation layer 120 that covers the side surface of the first semiconductor chip 110 and the surface of the first semiconductor chip 110 may be formed by a single lamination process, so that semiconductor package manufacturing processes may be simplified.

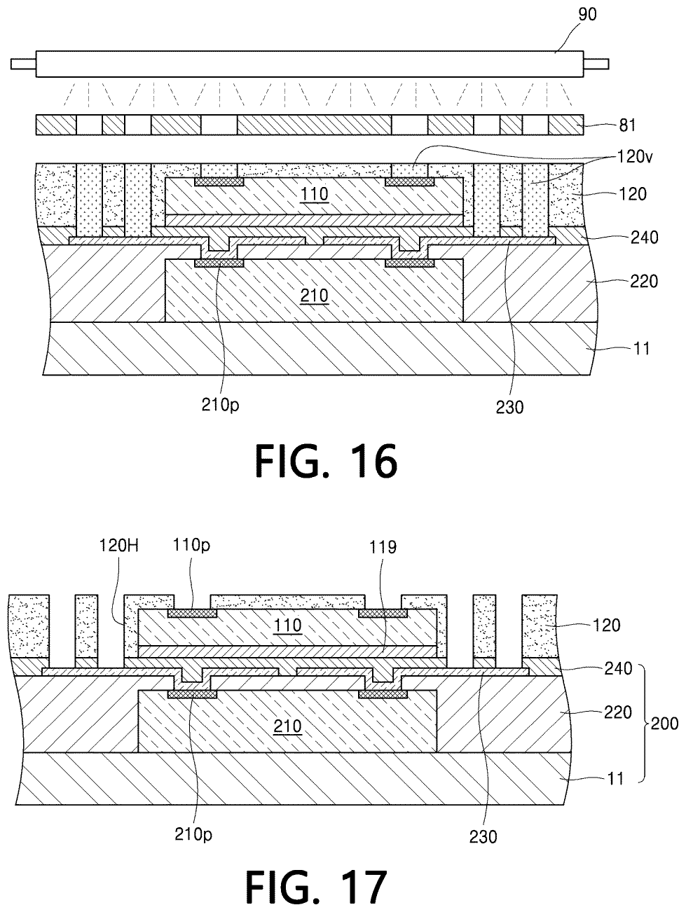

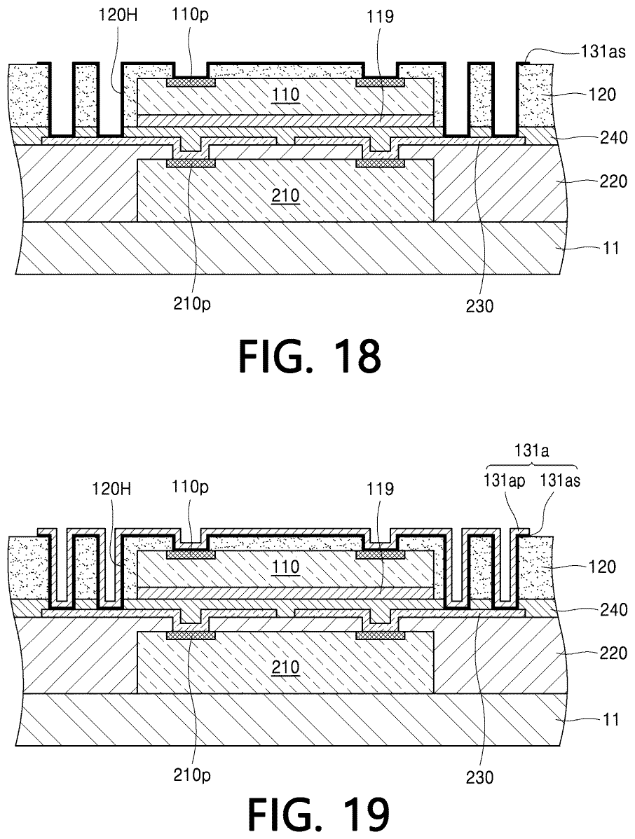

FIGS. 16 and 17 illustrate the operation of forming the through holes in the manufacturing method shown in FIG. 13. In the operation of forming the through hole, through holes 120H each passing through one side surface and the other side surface of the first encapsulation layer 120 and openings exposing the pads 110p of the first semiconductor chip 110 are formed. In FIGS. 16 and 17, a lower surface of the first encapsulation layer 120 facing the second semiconductor chip 210 is one side surface, and an upper surface of the first encapsulation layer 120 facing in a direction opposite to the second semiconductor chip 210 is the other side surface.

By removing portions of the first encapsulation layer 120, the through holes 120H vertically passing through the first encapsulation layer 120 to expose the second redistribution pattern 230 and the openings exposing the pads 110p of the first semiconductor chip 110 may be formed.

Referring to FIG. 16, a pattern mask 81 having a pattern of the through holes 120H and the openings to be formed in the first encapsulation layer 120 is disposed. In addition, an exposure region 120v is formed in the first encapsulation layer 120 by performing an exposure process of irradiating the first encapsulation layer 120 with light through the pattern mask 81 using a light source 90.

Subsequent to the exposure process, a development process is performed to remove the exposure region 120v by bringing it into contact with a developing solution, leaving only a portion of the first encapsulation layer 120.

The embodiments are not limited by the positive photosensitive method illustrated in FIG. 16, and a negative method of removing a portion of the resist layer exposed to light may be used.

Upon completion of the exposure process and the development process, as shown in FIG. 17, the first encapsulation layer 120 may include the openings for exposing the pads 110p of the first semiconductor chip 110 and the through holes 120H passing through the first encapsulation layer 120 to expose the second redistribution pattern 230.

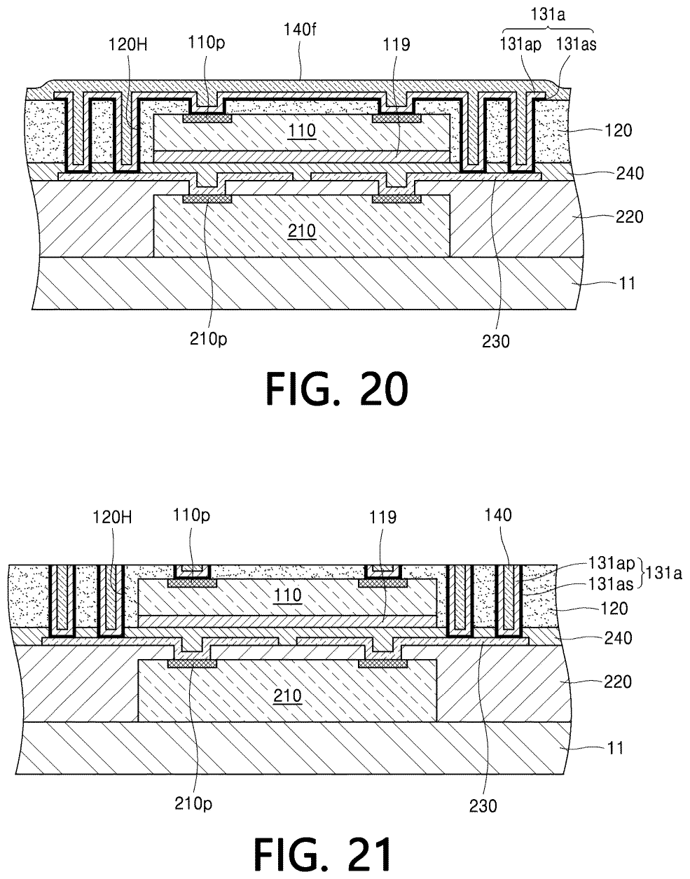

Referring to FIGS. 18 to 25, first redistribution structures 130 and 140d may be formed on the first encapsulation layer 120 and the first semiconductor chip 110. In order to form the first redistribution structures 130 and 140d, a first sub-redistribution pattern 131, a first insulating pattern 140d, and a second sub-redistribution pattern 133 may be sequentially formed.

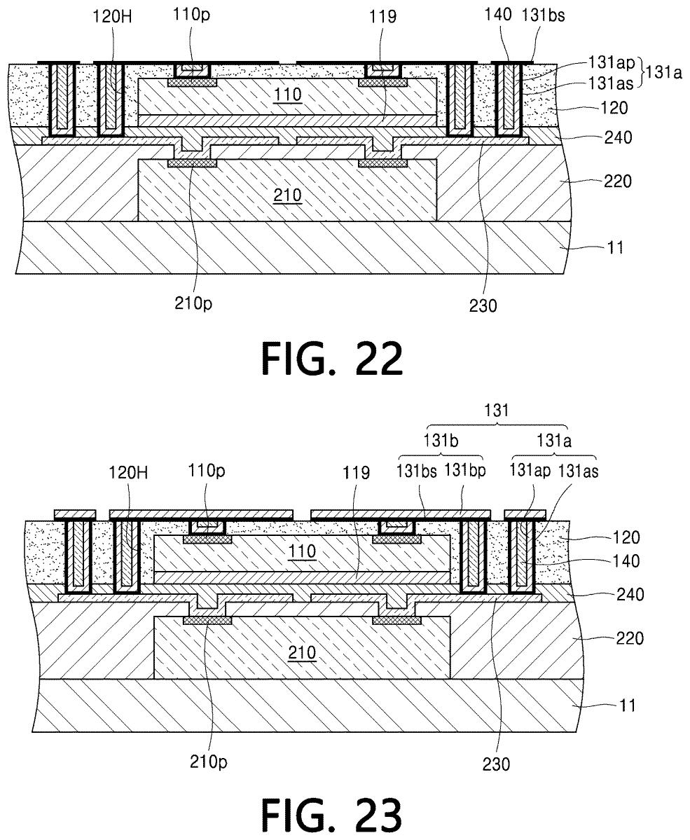

FIGS. 18 and 19 illustrate the operation of forming the first conductive layer in the manufacturing method illustrated in FIG. 13. FIG. 18 illustrates an operation of forming a first seed layer 131as, as part of the operation of forming the first conductive layer. FIG. 19 illustrates an operation of forming a first plating layer 131ap, as another part of the operation of forming the first conductive layer.

Referring to FIG. 18, in the operation of forming the first seed layer 131as, the first seed layer 131as is formed to cover inner surfaces of the through holes 120H and the other side surface of the first encapsulation layer 120. The first seed layer 131as may cover portions of the second redistribution pattern 230, which were exposed to the outside through the through holes 120H.

The operation of forming the first seed layer 131as may include, for example, a sputtering deposition process performed over the entirety of the other side surface of the first encapsulation layer 120. In the sputtering deposition process, for example, a metal material such as, titanium (Ti), copper, gold, silver, or palladium is used as a target to form the first seed layer 131as, which is a metal thin film covering the other side surface of the first encapsulation layer 120 and the inner surfaces of the through holes 120H, by metal atoms.

Referring to FIG. 19, in the operation of forming the first plating layer 131ap, the first plating layer 131ap is formed on a surface of the first seed layer 131as covering the inner surfaces of the through holes 120H and the other side surface of the first encapsulation layer 120. The first plating layer 131ap may be formed to be thicker than the first seed layer 131as is formed.

The first plating layer 131ap is formed by performing a plating process using, for example, a metal material such as copper, gold, silver, nickel, or palladium. The plating process may include at least one of an electroplating process and an electroless plating process.

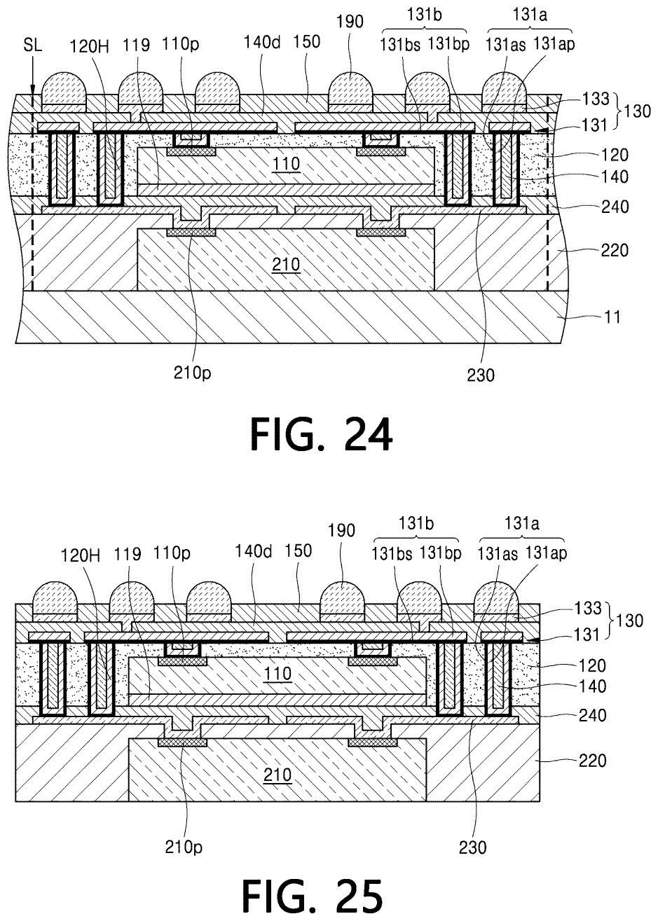

FIG. 20 illustrates the operation of forming the insulating layer in the manufacturing method illustrated in FIG. 13. In the operation of forming the insulating layer, an insulating layer 140f is formed that covers the entire surface of the first seed layer 131as, the first plating layer 131ap, and the first encapsulation layer 120 and fills inner spaces of the through holes 120H. The insulating layer 140f may include, for example, an electrically insulating resin.

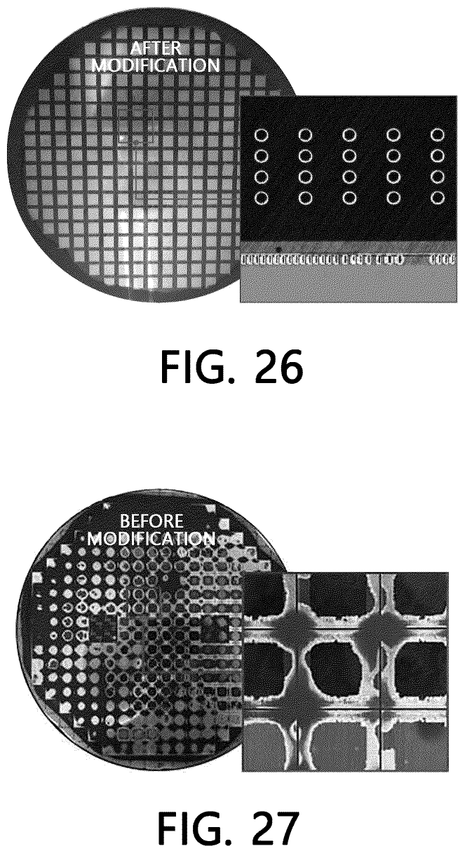

FIG. 21 illustrates the surface planarization operation in the manufacturing method illustrated in FIG. 13. In the surface planarization operation, a portion of the insulating layer 140f exposed to the outside at the other side surface of the first encapsulation layer 120 and a portion of the first plating layer 131ap covering the other side surface of the first encapsulation layer 120 are removed.

The surface planarization operation may be performed, for example, by irradiating the surface of the insulating layer with a laser or removing and/or polishing the surface of the insulating layer using a polishing brush.

Referring to FIG. 21, the first plating layer 131ap covering the upper surface of the first encapsulation layer 120 is removed together with the insulating layer 140f exposed at the upper surface of the first encapsulation layer 120, and the first seed layer 131as, the first plating layer 131ap, and the filling portion 140 remain in the through holes 120H of the first encapsulation layer 120.

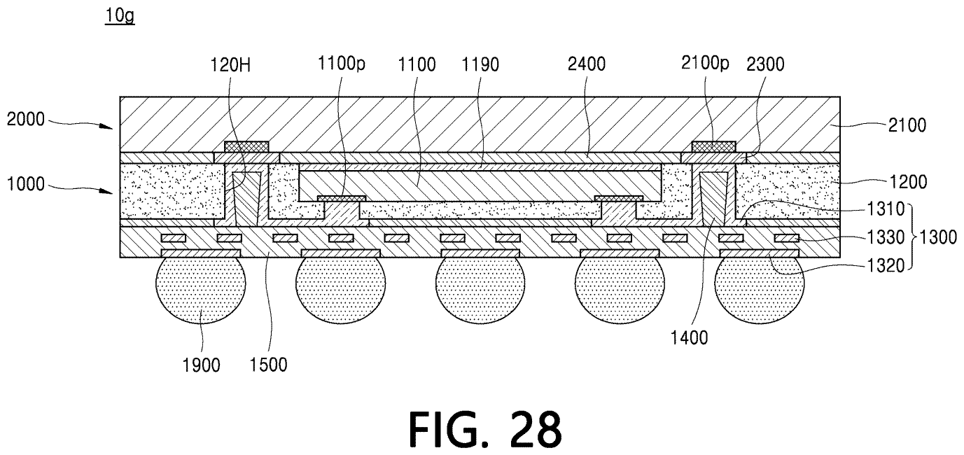

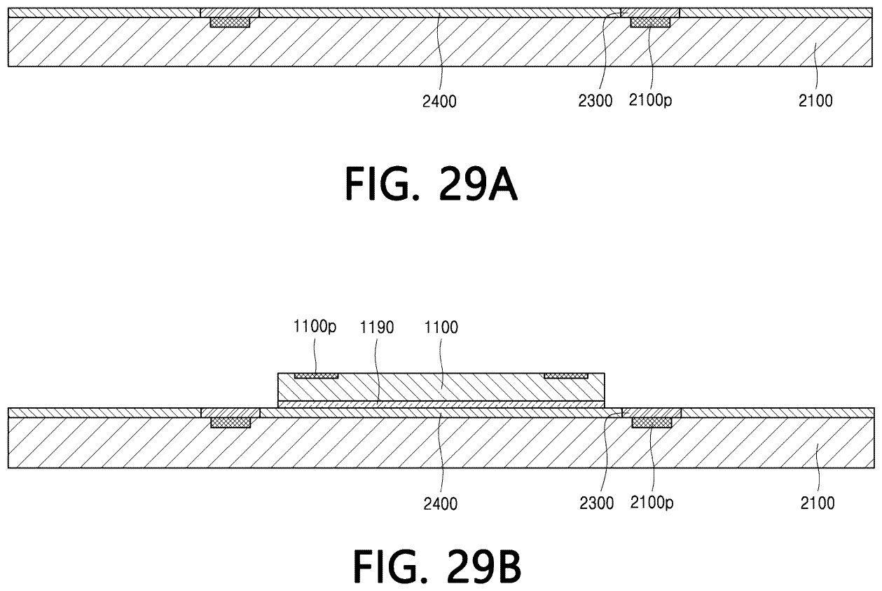

FIGS. 22 and 23 illustrate the operation of forming a second conductive layer 131b on the other side surface of the first encapsulation layer 120 in the manufacturing method illustrated in FIG. 13. The operation of forming the second conductive layer 131b is an operation of connecting the pads 110p of the first semiconductor chip 110 and a first conductive layer 131a disposed on the inner surfaces of the through holes 120H.

FIG. 22 illustrates an operation of forming a second seed layer 131bs, as part of the operation of forming the second conductive layer 131b. FIG. 23 illustrates an operation of forming a second plating layer 131bp, as another part of the operation of forming the second conductive layer 131b.

Referring to FIG. 22, in the operation of forming the second seed layer 131bs, the second seed layer 131bs that connects the pads 110p of the first semiconductor chip 110 to the first conductive layer 110a disposed on the inner surfaces of the through holes 120H is formed.

The operation of forming the second seed layer 131bs may include, for example, a sputtering deposition process performed on the other side surface of the first encapsulation layer 120. In the sputtering deposition process, a metal material such as titanium (Ti), copper, gold, silver, or palladium is used as a target to form the second seed layer 131bs, which is a metal thin film covering a portion of the other side surface of the first encapsulation layer 120, by metal atoms.

Referring to FIG. 23, in the operation of forming the second plating layer 131bp, the second plating layer 131bp is formed on a surface of the second seed layer 131bs. The second plating layer 131bp may be formed to be thicker than the second seed layer 131bs.

The second plating layer 131bp is formed by performing a plating process using, for example, a metal material such as copper, gold, silver, nickel, or palladium. The plating process may include at least one of an electroplating process and an electroless plating process.

The first sub-redistribution pattern 131 completed by the above-described operations is formed on the first encapsulation layer 120 to be connected to the pads 110p of the first semiconductor chip 110, and extends along the through holes 120H of the first encapsulation layer 120 to be connected to the second redistribution pattern 230.

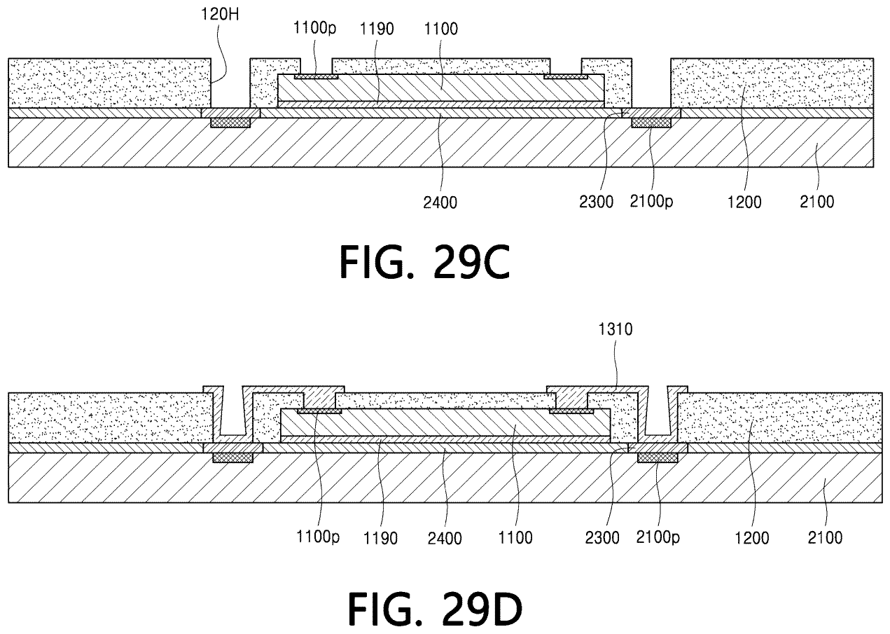

Referring to FIG. 24, after forming the first sub-redistribution pattern 131 on the first encapsulation layer 120 and the first semiconductor chip 110, the first redistribution structures 130 and 140d are completed by sequentially forming the first insulating pattern 140d and the second sub-redistribution pattern 133.

After forming the first sub-redistribution pattern 131, in order to form the first insulating pattern 140d, an insulating film may be formed on the first encapsulation layer 120 and the first sub-redistribution pattern 131, and portions of the insulating film may be removed so that openings for exposing portions of the first sub-redistribution pattern 131 are formed.

After forming the first insulating pattern 140d, the second sub-redistribution pattern 133 is formed on the first insulating pattern 140d. The second sub-redistribution pattern 133 may be formed to be connected to the first sub-redistribution pattern 131 through the first insulating pattern 140d. For example, the second sub-redistribution pattern 133 may be formed through a seed film forming process, a mask process, and an electroplating process.

Thereafter, a protective layer 150 is formed on the first insulating pattern 140d. The protective layer 150 may be formed to have openings exposing portions of the second sub-redistribution pattern 133. After forming the protective layer 150, external connection terminals 190 may be attached onto the second sub-redistribution pattern 133 exposed by the openings of the protective layer 150. The external connection terminal 190 may be, for example, a solder ball or bump.

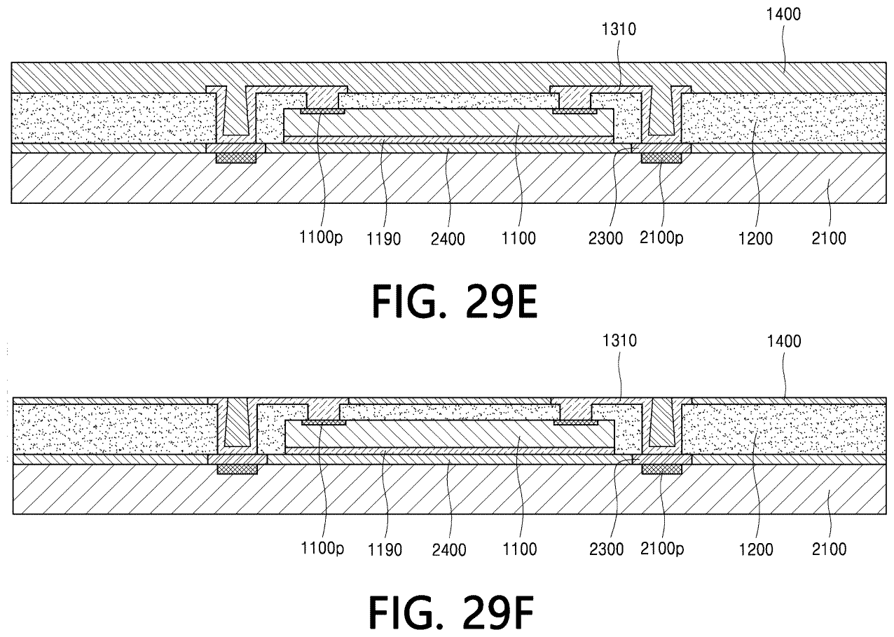

Referring to FIG. 25, the carrier 11 (see FIG. 24) is removed, and the semiconductor packages are singulated into individual semiconductor packages through a sawing process. That is, the semiconductor package illustrated in FIG. 24 may be cut off along a scribe lane SL (see FIG. 24) and may be separated into a plurality of individual semiconductor packages.

In the semiconductor package 10 manufactured by the manufacturing method of the above-described embodiment, an electrical connection between the second package 200 and the first package 100 may be made through a connection between the first redistribution pattern 130 and the second redistribution pattern 230. Specifically, since the first conductive layer 131a is directly connected to the second redistribution pattern 230 through the through holes 120H, the pads 210p of the second semiconductor chip 210 are electrically connected to the first redistribution pattern 130.

According to the manufacturing method of the above-described embodiment, the first sub-redistribution pattern 131 includes the first conductive layer 131a disposed in the through hole 120H, and the second conductive layer 131b that is distinct from the first conductive layer 131a and disposed on the other side surface of the first encapsulation layer 120. That is, since the first conductive layer 131a, which is disposed along the through holes 120H for electrical connection of the first package 100 and the second package 200, and the second conductive layer 131b for electrical connection of the first conductive layer 131a and the first semiconductor chip 110 of the first package 100 are formed independently of each other, the reliability of the overall electrical connection structure of the semiconductor package 10 may be improved.

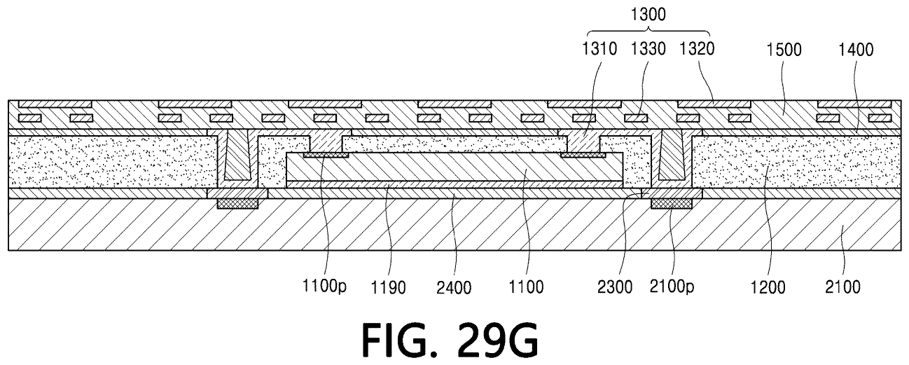

FIG. 26 illustrates a photograph and an enlarged photograph obtained by photographing a portion of the operations of the method of manufacturing the semiconductor package according to exemplary embodiments of the present invention. Specifically, FIG. 26 is a photograph of the semiconductor package in manufacture taken after the operation of removing portions of the insulating layer and the first conductive layer in the manufacturing method illustrated in FIG. 13.

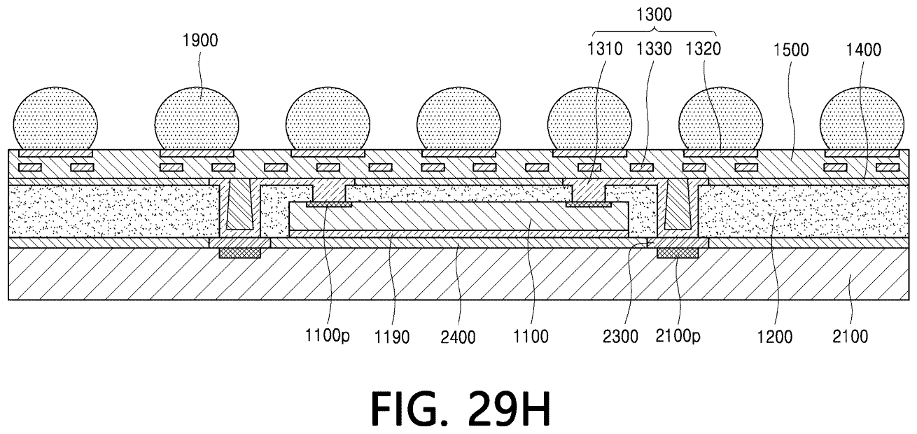

FIG. 27 illustrates a photograph and an enlarged photograph obtained by photographing a portion of operations of a method of manufacturing another semiconductor package according to a comparative example of the embodiment.

Unlike the method of manufacturing the semiconductor package according to the embodiment illustrated in FIGS. 13 to 25, in the method of manufacturing the semiconductor package according to the comparative example illustrated in FIG. 27, the insulating layer was disposed after forming the conductive layer, which is disposed in the through holes of the encapsulation portion, and the conductive layer, which is disposed on the surface of the encapsulation portion, at once by one process, and then the insulating layer is removed.

Referring to FIG. 27, the conductive layer disposed in the through holes and the conductive layer disposed on the surface of the encapsulation portion were continuously formed as a single layer, and then the insulating layer and a portion of the conductive layer on the surface of the encapsulation portion were removed together, which resulted in a problem that the conductive layer on the surface of the encapsulation portion was not uniformly removed and a circuit pattern intended to be formed on the surface of the encapsulation portion was lost.

The problem of circuit pattern loss occurs because there is a limit to precisely controlling thicknesses of the insulating layer and the conductive layer to be removed in the process of removing both the conductive layer on the surface of the encapsulation portion and the insulating layer. A removal device (e.g., a laser drill, a mechanical drill, or the like) used for the process of mechanically removing the insulating layer and the conductive layer on the surface of the encapsulation portion has a margin required for operation. In order to avoid the circuit pattern loss when the insulating layer and the conductive layer are removed, the thickness of the conductive layer should be set to be thick in consideration of the margin of the removal device.

Thus, in order to apply the process of removing the insulating layer and the conductive layer on the surface of the encapsulation portion, the conductive layer should be formed at least several times (e.g., five times) thicker than a conductive layer required to function as the circuit pattern. In order to form the conductive layer with a large thickness on the surface of the encapsulation portion, the time and cost of the plating process is greatly increased.

Unlike the comparative example illustrated in FIG. 27, referring to FIG. 26, the advantages of the manufacturing method for independently forming the first conductive layer, which is disposed on the inner surfaces of the through holes of the first encapsulation layer, and the second conductive layer, which is disposed on the other side surface of the first encapsulation layer, are shown. FIG. 26 illustrates a state in which the first conductive layer is formed on the inner surfaces of the through holes of the first encapsulation layer and the other side surface of the first encapsulation layer, and the insulating layer covering the other side surface of the first encapsulation layer is formed, and then the insulating layer and the first conductive layer on the other side surface of the first encapsulation layer are removed together.

In the state shown in FIG. 26, the second conductive layer can be formed on the other side surface of the first encapsulation layer, so that the loss of the circuit pattern completed by the second conductive layer may be completely prevented. Accordingly, the reliability of the semiconductor package is improved.

In addition, since the second conductive layer is formed independently of the first conductive layer, the thickness of the second conductive layer may be formed to be small without having to consider the margin of the removal device. Thus, the time and cost required for the plating process for forming the second conductive layer may be greatly reduced.

In addition, since the thickness of the circuit pattern formed by the second conductive layer is formed to be very small, the overall thickness of the semiconductor package may be manufactured to be small, and damage to the circuit pattern may be minimized even when an impact such as warpage acts on the semiconductor package.

In the semiconductor package according to another embodiment of the present invention, the semiconductor package 10 may be included in the semiconductor packages 10c, 10d, 10e, and 10f illustrated in FIGS. 8 to 11.

According to an exemplary embodiment of the present invention, the semiconductor package 10 illustrated in FIG. 12 may be included in the semiconductor package 10c illustrated in FIG. 8. That is, each of the first package 310, the second package 320, and the third package 330 illustrated in FIG. 8 may be replaced with the first package 100 illustrated in FIG. 12, and the fourth package 340 illustrated in FIG. 8 may be replaced with the second package 200 illustrated in FIG. 12. Accordingly, the first package 310, the second package 320, and the third package 330 may have technical features similar to those of the first package 100 described above with reference to FIG. 12, and the fourth package 340 may have technical features similar to those of the second package 200 described above with reference to FIG. 12. Other than changes in the structure of each of the first package 310, the second package 320, the third package 330, and the fourth package 340, the technical features of the semiconductor package 10c described in FIG. 8 may also be applicable to the present exemplary embodiment.

According to an exemplary embodiment of the present invention, the semiconductor package 10 illustrated in FIG. 12 may be included in the semiconductor package 10d illustrated in FIG. 9. That is, each of the first package 310, the second package 320, and the third package 330 illustrated in FIG. 9 may be replaced with the first package 100 illustrated in FIG. 12, and the fourth package 340 illustrated in FIG. 9 may be replaced with the second package 200 illustrated in FIG. 12. Accordingly, the first package 310, the second package 320, and the third package 330 may have technical features similar to those of the first package 100 described above with reference to FIG. 12, and the fourth package 340 may have technical features similar to those of the second package 200 described above with reference to FIG. 12. Other than changes in the structure of each of the first package 310, the second package 320, the third package 330, and the fourth package 340, the technical features of the semiconductor package 10d described in FIG. 9 may also be applicable to the present exemplary embodiment.

According to an exemplary embodiment of the present invention, the semiconductor package 10 illustrated in FIG. 12 may be included in the semiconductor package 10e illustrated in FIGS. 10A and 10B. That is, the first sub-redistribution pattern 431 illustrated in FIGS. 10A and 10B may be replaced with the first sub-redistribution pattern 131 illustrated in FIG. 12. Accordingly, the first sub-redistribution pattern 431 illustrated in FIGS. 10A and 10B may have technical features similar to those of the first sub-redistribution pattern 131 described with reference to FIG. 12. Other than a change in the structure of the first sub-redistribution pattern 431, the technical features of the semiconductor package 10e described in FIGS. 10A and 10B may also be applicable to the present exemplary embodiment.

According to an exemplary embodiment of the present invention, the semiconductor package 10 illustrated in FIG. 12 may be included in the semiconductor package 10f illustrated in FIG. 11. That is, the first sub-redistribution pattern 431 of the lower package 610 illustrated in FIG. 11 may be replaced with the first sub-redistribution pattern 131 illustrated in FIG. 12. In addition, each of the first package 310, the second package 320, and the third package 330 of the upper package 620 illustrated in FIG. 11 may be replaced with the first package 100 illustrated in FIG. 12, and the fourth package 340 of the upper package 620 illustrated in FIG. 11 may be replaced with the second package 200 illustrated in FIG. 12.

Accordingly, the first sub-redistribution pattern 431 illustrated in FIG. 11 may have technical features similar to those of the first sub-redistribution pattern 131 described with reference to FIG. 12. In addition, the first package 310, the second package 320, and the third package 330 illustrated in FIG. 11 may have technical features similar to those of the first package 100 described above with reference to FIG. 12, and the fourth package 340 illustrated in FIG. 11 may have technical features similar to those of the second package 200 described above with reference to FIG. 12. Other than a change in the structure of each of the first package 310, the second package 320, the third package 330, the fourth package 340, and the first sub-redistribution pattern 431, the technical features of the semiconductor package 10F described in FIG. 11 may also be applicable to the present exemplary embodiment.

Embodiments are not limited by the exemplary structure of the semiconductor package 10 illustrated in the above drawings, and the semiconductor package 10 may be modified in various forms. For example, the semiconductor package 10 can be transformed into at least one of several forms, including chip-on panel (COP), chip-on wafer (COW), and POP.

For example, when the semiconductor package 10 is manufactured in the form of COP, the second package 200 may have a structure in which the second semiconductor chip is attached onto a surface of a panel or a structure in which the second semiconductor chip is embedded in the panel.

As another example, when the semiconductor package 10 is manufactured in the form of COW, the second package 200 may include a second semiconductor chip formed directly on a wafer and elements such as pads and wiring.

Hereinafter, exemplary structures of the semiconductor package 10 according to embodiments will be described with reference to the drawings.

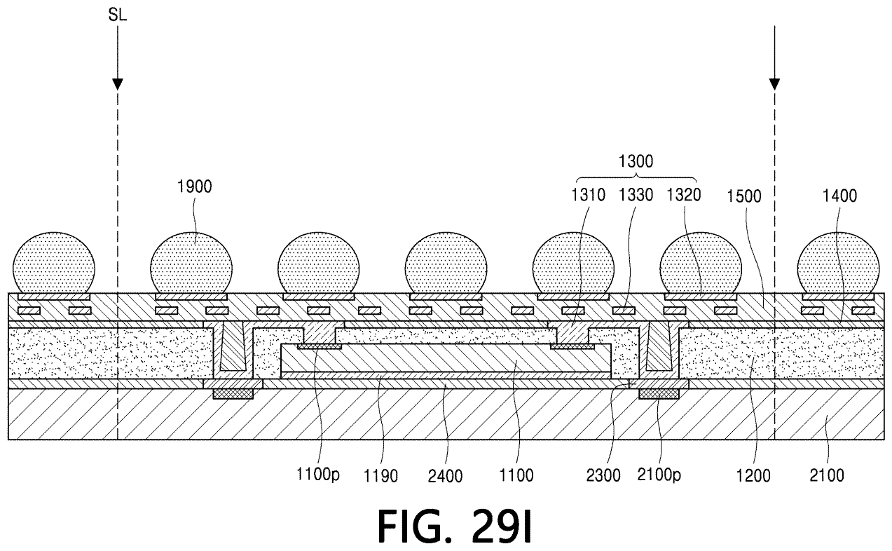

FIG. 28 is a cross-sectional view illustrating a semiconductor package according to an exemplary embodiment of the present invention.

Referring to FIG. 28, a semiconductor package 10g may include a first package 1000 and a second package 2000. The semiconductor package 10g illustrated in FIG. 28 is a semiconductor package fabricated in the form of COW, and may include a semiconductor package having a fan-in wafer level package (FIWLP) structure.

The first package 1000 may include a first semiconductor chip 1100. The first semiconductor chip 1100 may include a plurality of pads 1100p. The first semiconductor chip 1100 is implemented in substantially the same form as the first semiconductor chip 110 illustrated in FIG. 1, and thus a detailed description thereof will be omitted.

The first package 1000 may include a first encapsulation layer 1200 covering at least a portion of the first semiconductor chip 1100. The first encapsulation layer 1200 covers a side surface of the first semiconductor chip 1100, and may cover a lower surface of the first semiconductor chip 1100 on which the pads 1100p are provided. The first encapsulation layer 1200 may have openings for exposing the pads 1100p of the first semiconductor chip 1100.

The first encapsulation layer 1200 may include an insulating material. In exemplary embodiments, the first encapsulation layer 1200 may include a photosensitive material. For example, the first encapsulation layer 1200 may be formed of a polymer material such as polyimide. However, the material forming the first encapsulation layer 1200 is not limited thereto, and for example, the first encapsulation layer 1200 may include an EMC.

The first encapsulation layer 1200 may include through holes 120H vertically passing through the first encapsulation layer 1200. The through hole may be provided in a peripheral portion of the first semiconductor chip 1100.

The first package 1000 may include first redistribution structures 1300, 1400, and 1500 provided on the first semiconductor chip 1100. The first redistribution structures 1300, 1400, and 1500 may include a first redistribution pattern 1300, a first insulating pattern 1400, and an insulating layer 1500.

The first redistribution pattern 1300 may electrically connect the pads 1100p of the first semiconductor chip 1100 to external connection terminals 1900. In addition, the first redistribution pattern 1300 may be electrically connected to a second redistribution pattern 2300. Through the first redistribution pattern 1300 and the second redistribution pattern 2300, the first semiconductor chip 1100 may be electrically connected to a second semiconductor chip 2100, and the first semiconductor chip 1100 may be electrically connected to the external connection terminals 1900.

The first redistribution pattern 1300 may include a plurality of sub-redistribution patterns, and the sub-redistribution patterns may have a multilayer structure. For example, the first redistribution pattern 1300 may include a first sub-redistribution pattern 1310, a second sub-redistribution pattern 1320, and a third sub-redistribution pattern 1330.

The first sub-redistribution pattern 1310 is formed on the first encapsulation layer 1200, and may be connected to the pads 1100p of the first semiconductor chip 1100. A portion of the first sub-redistribution pattern 1310 may be connected to the second redistribution pattern 2300 through the first encapsulation layer 1200.

The first sub-redistribution pattern 1310 illustrated in FIG. 28 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 28 may include a first portion extending in the through hole 120H and a second portion connected to the first portion and extending on the first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 28 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 28 has been described above in detail, and thus a description thereof will be omitted.

The second sub-redistribution pattern 1320 is disposed on the insulating layer 1500. The second sub-redistribution pattern 1320 is connected to the external connection terminals 1900, and may be connected to the first sub-redistribution pattern 1310 through the third sub-redistribution pattern 1330.

The third sub-redistribution pattern 1330 is disposed on the insulating layer 1500. The third sub-redistribution pattern 1330 may be disposed between the first sub-redistribution pattern 1310 and the second sub-redistribution pattern 1320. The third sub-redistribution pattern 1330 may connect the first sub-redistribution pattern 1310 to the second sub-redistribution pattern 1320.

The first insulating pattern 1400 may be provided on a lower surface of the first encapsulation layer 1200 and a lower surface of the first sub-redistribution pattern 1310. The first insulating pattern 1400 covers the first sub-redistribution pattern 1310, and may have openings exposing portions of the first sub-redistribution pattern 1310.

The insulating layer 1500 extends on the first insulating pattern 1400, and may cover the first insulating pattern 1400 and the first sub-redistribution pattern 1310. The insulating layer 1500 may have openings for exposing the second sub-redistribution pattern 1320 to the outside.

The external connection terminal 1900 may be, for example, a solder ball or a solder bump. The external connection terminal 1900 may be electrically connected to the chip pads 1100p of the first semiconductor chip 1100 through the first redistribution pattern 1300. In addition, when the semiconductor package 10g is mounted on a circuit board, the external connection terminals 1900 are connected to substrate pads of the circuit board, and may be configured to physically/electrically connect the semiconductor package 10g to the circuit board.

The external connection terminal 1900 may be provided on the second sub-redistribution pattern 1320. The external connection terminal 1900 may include, for example, solder, tin (Sn), silver (Ag), indium (In), bismuth (Bi), antimony (Sb), copper (Cu), zinc (Zn), lead (Pb), and/or an alloy thereof. In exemplary embodiments, the external connection terminal 1900 may have a ball shape that is typically attached onto the second sub-redistribution pattern 1320. For example, the external connection terminal 1900 may be formed by positioning a solder ball on the second sub-redistribution pattern 1320 and then performing a reflow process on the solder ball. In other exemplary embodiments, the external connection terminal 1900 may be provided in the form of a plate, and may be formed to have a substantially uniform thickness on a surface of the second sub-redistribution pattern 1320.

The second package 2000 may include the second semiconductor chip 2100.

In exemplary embodiments, the second semiconductor chip 2100 may be, for example, a memory semiconductor chip. The second memory semiconductor chip 2100 may be, for example, a volatile memory semiconductor chip, such as a DRAM or an SRAM, or a nonvolatile memory semiconductor chip, such as a PRAM, an MRAM, a FeRAM or an RRAM. Alternatively, in exemplary embodiments, the second semiconductor chip 2100 may be a logic chip. For example, the second semiconductor chip 2100 may be a CPU, an MPU, a GPU, or an AP. A plurality of various types of individual devices may be formed in the second semiconductor chip 2100.

The second semiconductor chip 2100 may include a front side and a back side opposite to each other. The front side of the second semiconductor chip 2100 may be a pad surface on which pads 2100p are provided. The pads 2100p may be electrically connected to a semiconductor device formed in the second semiconductor chip 2100. In exemplary embodiments, the front side of the second semiconductor chip 2100 may be in contact with the first redistribution pattern 1300 through the second redistribution pattern 2300. Although not shown in detail, a passivation film may be formed on the front side of the second semiconductor chip 2100, and the passivation film may include openings that cover the front side but expose the pads 2100p.

The second package 2000 may include second redistribution structures 2300 and 2400 provided on the second semiconductor chip 2100. The second redistribution structures 2300 and 2400 may be provided on the front side of the second semiconductor chip 2100 and may include the second redistribution pattern 2300 and a second insulating pattern 2400.

The second redistribution pattern 2300 may electrically connect the pads 2100p of the second semiconductor chip 2100 to the first redistribution pattern 1300, and the second insulating pattern 2400 may extend on a surface of the second semiconductor chip 2100.

In an embodiment of the present invention, a connection between the second semiconductor chip 2100 and the first semiconductor chip 1100 may be made through a connection between the first redistribution pattern 1300 and the second redistribution pattern 2300.

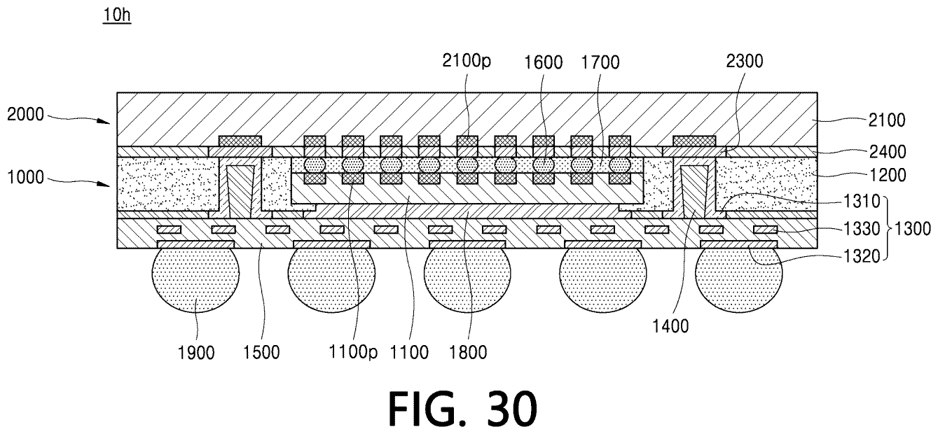

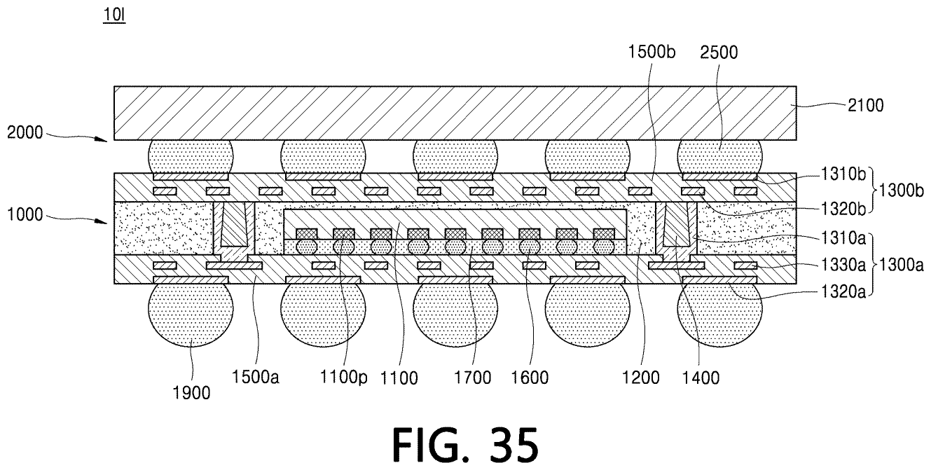

FIGS. 29A to 291 are cross-sectional views illustrating a method of manufacturing the semiconductor package according to exemplary embodiments of the present invention. Hereinafter, a method of manufacturing the semiconductor package 10g illustrated in FIG. 28 will be described with reference to FIGS. 29A to 291.

Referring to FIG. 29A, a second semiconductor chip 2100 in which second redistribution structures 2300 and 2400 are formed is prepared. A plurality of various types of individual devices may be formed in the second semiconductor chip 2100.

A second insulating pattern 2400 may be formed to cover a surface of the second semiconductor chip 2100 on which pads 2100p are provided. The second insulating pattern 2400 may be formed to have openings capable of exposing at least some of the pads 2100p. In addition, a second redistribution pattern 2300 is formed on the pads 2100p of the second semiconductor chip 2100. For example, the second redistribution pattern 2300 may be formed through a seed film forming process, a mask process, and an electroplating process. The second redistribution pattern 2300 may be connected to a first sub-redistribution pattern 1310 and the pads 2100p of the second semiconductor chip 2100.

In exemplary embodiments, the second insulating pattern 2400 may be formed through a film lamination process using a solid state insulating film having a uniform thickness. For example, in order to form the second insulating pattern 2400, an insulating film of a semi-cured state (i.e., B-stage) may be disposed on the second semiconductor chip 2100, and a predetermined heat and pressure may be applied to cure the insulating film. Thereafter, a patterning process on the cured insulating film may be performed. Since the second insulating pattern 2400 is formed using a solid state insulating film, the second insulating pattern 2400 may have a substantially uniform thickness.

Referring to FIG. 29B, a first semiconductor chip 1100 is disposed on the second insulating pattern 2400. An adhesive layer 1190 for fixing the first semiconductor chip 1100 may be provided between the first semiconductor chip 1100 and the second insulating pattern 2400. The adhesive layer 1190 may include, for example, a die attach film. In addition, the adhesive layer 1190 may include a material having high thermal conductivity so that heat of the first semiconductor chip 1100 may be effectively emitted.

Referring to FIG. 29C, after disposing the first semiconductor chip 1100, a first encapsulation layer 1200 covering the first semiconductor chip 1100 may be formed. The first encapsulation layer 1200 may be formed to have openings for exposing the pads 1100p of the first semiconductor chip 1100, and may be formed to have through holes 120H that pass through the first encapsulation layer 1200 so as to expose the second redistribution pattern 2300.

In exemplary embodiments of the present invention, the first encapsulation layer 1200 is formed by a lamination process using a polymer material such as polyimide and may cover a side surface of the first semiconductor chip 1100 and a surface of the first semiconductor chip 1100 on which the pads 1100p are provided.

Referring to FIG. 29D, the first sub-redistribution pattern 1310 is formed on the first encapsulation layer 1200 and the first semiconductor chip 1100. The first sub-redistribution pattern 1310 may be formed on the first encapsulation layer 1200, may be in contact with the pads 1100p of the first semiconductor chip 1100, and may extend along the through holes 120H of the first encapsulation layer 1200 to be in contact with the second redistribution pattern 2300. For example, the first sub-redistribution pattern 1310 may be formed through a seed film forming process, a mask process, and an electroplating process.

Referring to FIG. 29E, a first insulating pattern 1400 is formed on the first encapsulation layer 1200 and the first sub-redistribution pattern 1310. The first insulating pattern 1400 may be formed after forming the first sub-redistribution pattern 1310, and thus the first insulating pattern 1400 may cover a surface of each of the first encapsulation layer 1200 and the first sub-redistribution pattern 1310.

Referring to FIG. 29F, a planarization process may be performed on the surface of the first insulating pattern 1400 to remove a portion of the first insulating pattern 1400. The planarization process may be performed until the first sub-redistribution pattern 1310 is exposed. Alternatively, the planarization process may be performed to remove a portion of the first insulating pattern 1400 and a portion of the first sub-redistribution pattern 1310 together. The planarization process may include a chemical mechanical polishing, a grinding process, and the like. A portion of the first insulating pattern 1400 and a portion of the first sub-redistribution pattern 1310 may be planarized through the planarization process. The surface of the first insulating pattern 1400 exposed through the planarization process may be coplanar with a surface of the first sub-redistribution pattern 1310.

Referring to FIG. 29G, a second sub-redistribution pattern 1320, a third sub-redistribution pattern 1330, and an insulating layer 1500 are formed on the first insulating pattern 1400 and the first sub-redistribution pattern 1310. The insulating layer 1500 may be formed to have openings exposing portions of the second sub-redistribution pattern 1320.

Referring to FIG. 29H, after forming the insulating layer 1500, external connection terminals 1900 may be attached onto the second sub-redistribution pattern 1320 exposed by the openings of the insulating layer 1500. The external connection terminal 1900 may be, for example, a solder ball or bump.

Referring to FIG. 291, the semiconductor packages are singulated into individual semiconductor packages through a sawing process. That is, the semiconductor package illustrated in FIG. 29H may be cut off along a scribe lane SL and may be separated into a plurality of individual semiconductor packages.

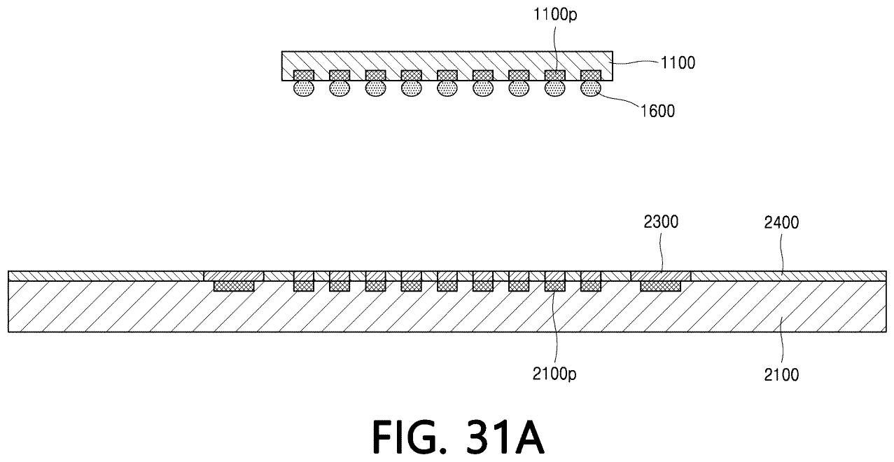

FIG. 30 is a cross-sectional view illustrating a semiconductor package according to an exemplary embodiment of the present invention.

Referring to FIG. 30, a semiconductor package 10h may include a first package 1000 and a second package 2000. The semiconductor package 10h illustrated in FIG. 30 is a semiconductor package fabricated in the form of COW, and may have substantially the same configuration as the semiconductor package 10g illustrated in FIG. 28. In FIG. 30, the same descriptions as those described above will be omitted or simply given.

The first package 1000 may include a first semiconductor chip 1100. The first semiconductor chip 1100 may include a plurality of pads 1100p. The plurality of pads 1100p may not be located on one surface of the first semiconductor chip 1100 facing an insulating layer 1500, but may be located on the other surface of the first semiconductor chip 1100 facing a second semiconductor chip 2100. Unlike the embodiment illustrated in FIG. 28, in the embodiment illustrated in FIG. 30, the pads 1100p of the first semiconductor chip 1100 and pads 2100p of the second semiconductor chip 2100 may be disposed to face each other.

The first package 1000 may include first redistribution structures 1300, 1400, and 1500 provided on the first semiconductor chip 1100. The first redistribution structures 1300, 1400, and 1500 may include a first redistribution pattern 1300, a first insulating pattern 1400, and the insulating layer 1500.

A first sub-redistribution pattern 1310 illustrated in FIG. 30 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 30 may include a first portion extending in a through hole 120H and a second portion connected to the first portion and extending on a first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 30 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 30 has been described above in detail, and thus, a description thereof will be omitted.

The first package 1000 may include internal connection terminals 1600. Each of the internal connection terminals 1600 is disposed between the pad 1100p of the first semiconductor chip 1100 and the pad 2100p of the second semiconductor chip 2100 to electrically connect the pad 1100p of the first semiconductor chip 1100 to the pad 2100p of the second semiconductor chip 2100. In embodiments of the present invention, a connection between the first semiconductor chip 1100 and the second semiconductor chip 2100 may be made through the internal connection terminals 1600.

The internal connection terminal 1600 may be, for example, a solder ball or a solder bump. The internal connection terminal 1600 may include, for example, solder, tin (Sn), silver (Ag), indium (In), bismuth (Bi), antimony (Sb), copper (Cu), zinc (Zn), lead (Pb), and/or an alloy thereof. The internal connection terminal 1600 may have a ball shape attached to the pad 1100p of the first semiconductor chip 1100.

The first package 1000 may include a gap-fill layer 1700. The gap-fill layer 1700 may fill a gap between the first semiconductor chip 1100 and the second semiconductor chip 2100, and may surround sidewalls of the internal connection terminals 1600 disposed between the first semiconductor chip 1100 and the second semiconductor chip 2100. In exemplary embodiments, the gap-fill layer 1700 may be formed of an underfill material such as, for example, an epoxy resin, or may be formed of a non-conductive film (NCF). In exemplary embodiments, the gap-fill layer 1700 may be formed of an epoxy molding compound.

The first package 1000 may include a heat dissipation pad 1800. The heat dissipation pad 1800 may be disposed on one surface of the first semiconductor chip 1100. The heat dissipation pad 1800 may include a material having a conductive material.

The second package 2000 may include the second redistribution pattern 2300. The second redistribution pattern 2300 of the second package 2000 may include a first portion connected to the first sub-redistribution pattern 1310 and a second portion connected to the internal connection terminal 1600.

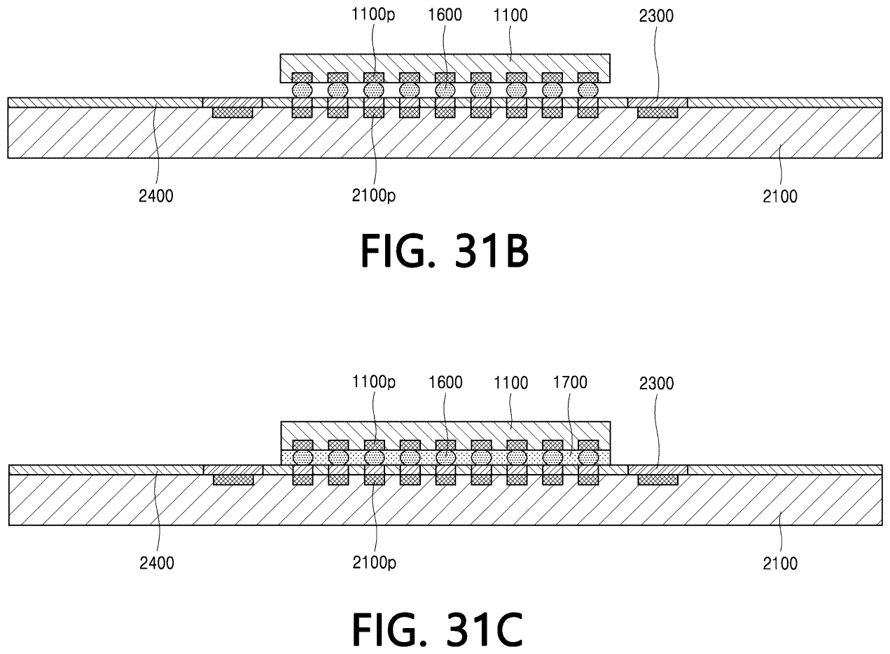

FIGS. 31A to 31E are cross-sectional views illustrating a method of manufacturing the semiconductor package according to exemplary embodiments of the present invention. Hereinafter, a method of manufacturing the semiconductor package 10h illustrated in FIG. 30 will be described with reference to FIGS. 31A to 31E.

Referring to FIG. 31A, a second semiconductor chip 2100 in which second redistribution structures 2300 and 2400 are formed is prepared. Specifically, a second insulating pattern 2400 may be formed to cover a surface of the second semiconductor chip 2100 on which pads 2100p are provided. The second insulating pattern 2400 may be formed to have openings capable of exposing at least some of the pads 2100p. In addition, a second redistribution pattern 2300 is formed on the pads 2100p of the second semiconductor chip 2100. For example, the second redistribution pattern 2300 may be formed through a seed film forming process, a mask process, and an electroplating process.

Referring to FIG. 31B, a first semiconductor chip 1100 is disposed on the second semiconductor chip 2100. Specifically, the first semiconductor chip 1100 is disposed on the second insulating pattern 2400 so that internal connection terminals 1600 are in contact with the second redistribution pattern 2300.

Referring to FIG. 31C, a gap-fill layer 1700 is formed between the first semiconductor chip 1100 and the second semiconductor chip 2100. The gap-fill layer 1700 may be formed through, for example, a capillary underfill process.

Referring to FIG. 31D, after forming the gap-fill layer 1700, a first encapsulation layer 1200 covering the first semiconductor chip 1100 may be formed. The first encapsulation layer 1200 may be formed to have through holes 120H passing through the first encapsulation layer 1200 to expose the second redistribution pattern 2300, and may be formed to have a pad hole 130H to expose one surface of the first semiconductor chip 1100.

Referring to FIG. 31E, a first sub-redistribution pattern 1310 and a heat dissipation pad 1800 are formed on the first encapsulation layer 1200 and the first semiconductor chip 1100. The first sub-redistribution pattern 1310 is formed on the first encapsulation layer 1200, and may extend along the through holes 120H of the first encapsulation layer 1200 to be in contact with the second redistribution pattern 2300. In addition, the heat dissipation pad 1800 are formed on the first encapsulation layer 1200 and the first semiconductor chip 1100, and may be in contact with the first semiconductor chip 1100 along the pad holes 130H of the first encapsulation layer 1200. For example, the first sub-redistribution pattern 1310 and the heat dissipation pad 1800 may be formed through a seed film forming process, a mask process, and an electroplating process.

Subsequently, the semiconductor package 10h may be manufactured through a method similar to the manufacturing method described with reference to FIGS. 29E to 291.

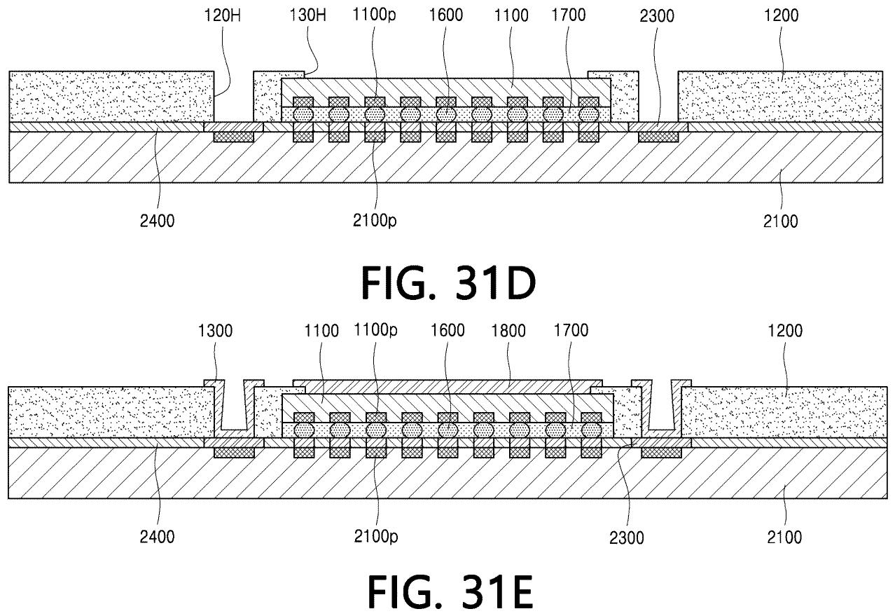

FIG. 32 is a cross-sectional view illustrating a semiconductor package according to an exemplary embodiment of the present invention.

Referring to FIG. 32, a semiconductor package 10i may include a first package 1000 and a second package 2000. The semiconductor package 10i illustrated in FIG. 32 is a semiconductor package fabricated in the form of COP, and may include a semiconductor package having a panel level package (PLP) structure.

The first package 1000 illustrated in FIG. 32 may have substantially the same configuration as the first package 1000 illustrated in FIG. 28. In FIG. 32, the same descriptions as those described above will be omitted or simply given.

A first sub-redistribution pattern 1310 illustrated in FIG. 32 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 32 may include a first portion extending in a through hole 120H and a second portion connected to the first portion and extending on a first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 32 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 32 has been described above in detail, and thus, a description thereof will be omitted.

The second package 2000 may be disposed on the first package 1000. The second package 2000 illustrated in FIG. 32 may have substantially the same configuration as the second package 2000 illustrated in FIG. 28, except that it includes a second encapsulation layer 2200 covering at least a portion of a second semiconductor chip 2100.

The second package 2000 may include the second semiconductor chip 2100. The second semiconductor chip 2100 may include pads 2100p. The second semiconductor chip 2100 may be a single semiconductor chip, but the present invention is not limited thereto. For example, the second semiconductor chip 2100 may be a stack of a plurality of semiconductor chips.

In exemplary embodiments, the second semiconductor chip 2100 may be, for example, a memory semiconductor chip. Alternatively, in exemplary embodiments, the second semiconductor chip 2100 may be a logic chip.

The second package 2000 may include the second encapsulation layer 2200 covering at least a portion of the second semiconductor chip 2100. In this case, a lower surface of the second encapsulation layer 2200 may be coplanar with a lower surface of the second semiconductor chip 2100.

The second encapsulation layer 2200 may include an insulating material. The second encapsulation layer 22000 may include a photosensitive material. For example, the second encapsulation layer 2200 may include a polymer material such as polyimide. However, the material forming the second encapsulation layer 2200 is not limited thereto, and for example, the second encapsulation layer 2200 may include an EMC.

The second package 2000 may include second redistribution structures 2300 and 2400 provided between the second encapsulation layer 2200 and a first encapsulation layer 1200. The second redistribution structures 2300 and 2400 may include a second redistribution pattern 2300 and a second insulating pattern 2400. The second redistribution pattern 2300 may extend along the second encapsulation layer 2200 and may be electrically connected to the pads 2100p of the second semiconductor chip 2100. The second insulating pattern 2400 may be formed to have openings for exposing the second redistribution pattern 2300, and the first sub-redistribution pattern 1310 and the second redistribution pattern 2300 may be connected through the openings of the second insulating pattern 2400.

In embodiments of the present invention, an electrical connection between the second package 2000 and the first package 1000 may be made through a connection between the first redistribution pattern 1300 and the second redistribution pattern 2300.

Hereinafter, a method of manufacturing the semiconductor package 10i illustrated in FIG. 32 will be described.

First, a second semiconductor chip 2100 having pads 2100p provided therein is disposed on a carrier substrate.

Thereafter, a second encapsulation layer 2200 covering the second semiconductor chip 2100 is formed. The second encapsulation layer 2200 may be formed to cover a side surface of the second semiconductor chip 2100, and a surface opposite one surface of the second semiconductor chip 2100 on which the pads 2100p are provided. In exemplary embodiments, in order to form the second encapsulation layer 2200, an insulating film is coated on the carrier substrate and the second semiconductor chip 2100, and portions of the insulating film may be removed so that the pads 2100p of the second semiconductor chip 2100 are exposed. The insulating film may include, for example, a photosensitive material.

Next, the carrier substrate is removed, and the second semiconductor chip 2100 on which the second encapsulation layer 2200 is formed is turned upside down and disposed.

Thereafter, second redistribution structures 2300 and 2400 are formed on the second semiconductor chip 2100 and the second encapsulation layer 2200. A second insulating pattern 2400 may be formed to cover the surface of the second semiconductor chip 2100 on which the pads 2100p are provided. The second insulating pattern 2400 may be formed to have openings capable of exposing at least some of the pads 2100p. In addition, a second redistribution pattern 2300 is formed on the pads 2100p of the second semiconductor chip 2100. For example, the second redistribution pattern 2300 may be formed through a seed film forming process, a mask process, and an electroplating process.

Subsequently, the semiconductor package 10i may be manufactured through a method similar to the manufacturing method described with reference to FIGS. 29B to 291.

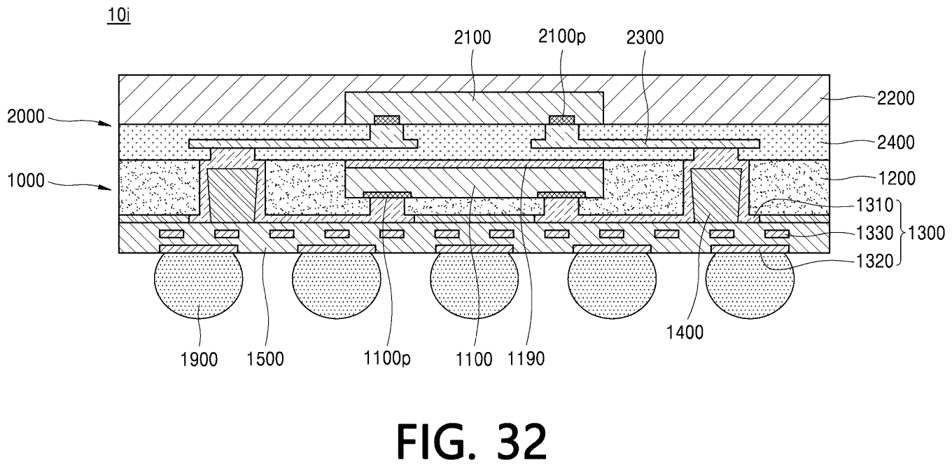

FIG. 33 is a cross-sectional view illustrating a semiconductor package according to an exemplary embodiment of the present invention.

Referring to FIG. 33, a semiconductor package 10j may include a first package 1000 and a second package 2000. The semiconductor package 10j illustrated in FIG. 33 is a semiconductor package fabricated in the form of COP, and may include a semiconductor package having a PLP structure.

The first package 1000 illustrated in FIG. 33 may have substantially the same configuration as the first package 1000 illustrated in FIG. 30. In FIG. 33, the same descriptions as those described above will be omitted or simply given.

That is, in the embodiment illustrated in FIG. 33, pad 1100p of the first semiconductor chip 1100 may not be located on one surface of the first semiconductor chip 1100 facing an insulating layer 1500, and may be located on the other surface of the first semiconductor chip 1100 facing a second semiconductor chip 2100. Unlike the embodiment illustrated in FIG. 32, in the embodiment illustrated in FIG. 33, the pads 1100p of the first semiconductor chip 1100 and pads 2100p of the second semiconductor chip 2100 may be disposed to face each other.

A first sub-redistribution pattern 1310 illustrated in FIG. 33 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 33 may include a first portion extending in a through hole 120H and a second portion connected to the first portion and extending on a first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 33 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 33 has been described above in detail, and thus, a description thereof will be omitted.

The second package 2000 may be disposed on the first package 1000. The second package 2000 illustrated in FIG. 33 may have substantially the same configuration as the second package 2000 illustrated in FIG. 30 except that it includes a second encapsulation layer 2200 covering at least a portion of the second semiconductor chip 2100.

The second package 2000 may include the second semiconductor chip 2100. The second semiconductor chip 2100 may include pads 2100p. The second semiconductor chip 2100 may be a single semiconductor chip, but the present invention is not limited thereto. For example, the second semiconductor chip 2100 may be a stack of a plurality of semiconductor chips.

In exemplary embodiments, the second semiconductor chip 2100 may be, for example, a memory semiconductor chip. Alternatively, in exemplary embodiments, the second semiconductor chip 2100 may be a logic chip.

The second package 2000 may include the second encapsulation layer 2200 covering at least a portion of the second semiconductor chip 2100. In this case, a lower surface of the second encapsulation layer 2200 may be coplanar with a lower surface of the second semiconductor chip 2100.

The second encapsulation layer 2200 may include an insulating material. In exemplary embodiments, the second encapsulation layer 2200 may include a photosensitive material. For example, the second encapsulation layer 2200 may include a polymer material such as polyimide. However, the material forming the second encapsulation layer 2200 is not limited thereto, and for example, the second encapsulation layer 2200 may include an EMC.

The second package 2000 may include second redistribution structures 2300 and 2400 provided between the second encapsulation layer 2200 and a first encapsulation layer 1200. The second redistribution structures 2300 and 2400 may include a second redistribution pattern 2300 and a second insulating pattern 2400.

The second redistribution pattern 2300 may include a first portion connected to the first sub-redistribution pattern 1310 and a second portion connected to internal connection terminals 1600. The second redistribution pattern 2300 may extend along the second encapsulation layer 2200 and may be electrically connected to the pads 2100p of the second semiconductor chip 2100.

The second insulating pattern 2400 may be formed to have openings for exposing the second redistribution pattern 2300. Through the openings of the second insulating pattern 2400, the second redistribution pattern 2300 may be connected to the internal connection terminals 1600, and the second redistribution pattern 2300 may be connected to the first sub-redistribution pattern 1310.

The semiconductor package 10j illustrated in FIG. 33 may be manufactured in almost the same manner as the semiconductor package 10i illustrated in FIG. 32, and thus, a detailed description thereof will be omitted.

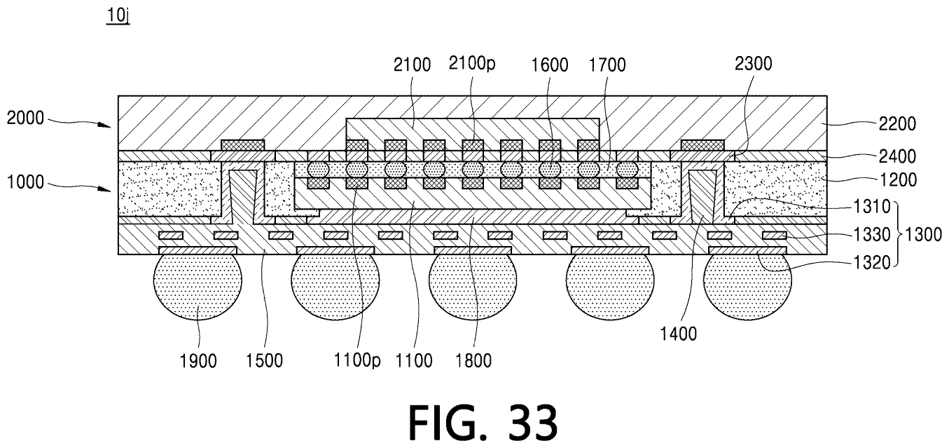

FIG. 34 is a cross-sectional view illustrating a semiconductor package according to an exemplary embodiment of the present invention.

Referring to FIG. 34, a semiconductor package 10k may include a first package 1000 and a second package 2000. The semiconductor package 10k illustrated in FIG. 34 may be a semiconductor package having a PoP structure in which the second package 2000 is attached to the first package 1000.

The first package 1000 may be a semiconductor package having a fan-out structure. The first package 1000 may include a first semiconductor chip 1100. The first semiconductor chip 1100 may include a plurality of pads 1100p. The first semiconductor chip 1100 is implemented substantially the same as the first semiconductor chip illustrated in FIG. 1, and thus a detailed description thereof will be omitted.

The first package 1000 may include a first encapsulation layer 1200 covering at least a portion of the first semiconductor chip 1100. The first encapsulation layer 1200 covers a side surface of the first semiconductor chip 1100, and may cover a lower surface of the first semiconductor chip 1100 on which the pads 1100p are provided. The first encapsulation layer 1200 may have openings for exposing the pads 1100p of the first semiconductor chip 1100.

The first encapsulation layer 12000 may include an insulating material. In exemplary embodiments, the first encapsulation layer 1200 may include a photosensitive material. For example, the first encapsulation layer 1200 may be formed of a polymer material such as polyimide. However, the material forming the first encapsulation layer 1200 is not limited thereto, and for example, the first encapsulation layer 1200 may include an EMC.

The first encapsulation layer 1200 may include through holes vertically passing through the first encapsulation layer 1200. The through hole may be provided in a peripheral portion of the first semiconductor chip 1100.

The first package 1000 may include the first encapsulation layer 1200 and first redistribution structures 1300a, 1400, and 1500a provided in the first semiconductor chip 1100.

The first redistribution structures 1300a, 1400, and 1500a may include a first redistribution pattern 1300a, a first insulating pattern 1400, and a first insulating layer 1500a.

The first redistribution pattern 1300a may electrically connect the pads 1100p of the first semiconductor chip 1100 to external connection terminals 1900. In addition, the first redistribution pattern 1300a may be electrically connected to package connection terminals 2500 of the second package 2000 through a second redistribution pattern 1300b. The first package 1000 may be electrically connected to the second package 2000 through the first redistribution pattern 1300a and the package connection terminals 2500.

The first redistribution pattern 1300a may include a plurality of sub-redistribution patterns, and the sub-redistribution patterns may have a multilayer structure. For example, the first redistribution pattern 1300a may include a first sub-redistribution pattern 1310a, a second sub-redistribution pattern 1320a, and a third sub-redistribution pattern 1330a.

The first redistribution structures 1300a, 1400, and 1500a and the external connection terminal 1900 illustrated in FIG. 34 are substantially the same as those described with reference to FIG. 28, and thus, detailed descriptions thereof will be omitted.

The first sub-redistribution pattern 1310 illustrated in FIG. 34 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 34 may include a first portion extending in a through hole 120H and a second portion connected to the first portion and extending on the first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 34 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 34 has been described above in detail, and thus, a description thereof will be omitted.

The first package 1000 may include second redistribution structures 1300b and 1500b. The second redistribution structures 1300b and 1500b may be formed on the other surface opposite to one surface of the first encapsulation layer 1200. The first redistribution structures 1300a, 1400, and 1500a may be formed on one surface of the first encapsulation layer 1200.

The second redistribution structures 1300b and 1500b may include the second redistribution pattern 1300b and a second insulating layer 1500b.

The second redistribution pattern 1300b may electrically connect the first redistribution pattern 1300a to the package connection terminals 2500. Through the second redistribution pattern 1300b, the first semiconductor chip 1100 may be electrically connected to the package connection terminals 2500, and the first package 1000 may be electrically connected to the second package 2000.

The second redistribution pattern 1300b may include a plurality of sub-redistribution patterns, and the sub-redistribution pattern may have a multilayer structure. For example, the second redistribution pattern 1300b may include a first sub-redistribution pattern 1310b and a second sub-redistribution pattern 1320b.

The first sub-redistribution pattern 1310b extends from the second insulating layer 1500b. The first sub-redistribution pattern 1310b may be connected to the package connection terminals 2500 and may be connected to the first redistribution pattern 1300a through the second sub-redistribution pattern 1320b.

The second sub-redistribution pattern 1320b extends from the second insulating layer 1500b, and may be disposed between the first sub-redistribution patterns 1310a and 1310b. The second sub-redistribution pattern 1320b may connect the first sub-redistribution patterns 1310a and 1310b to each other.

The second insulating layer 1500b may be provided on an upper surface of the first encapsulation layer 1200 and an upper surface of the first semiconductor chip 1100. The second insulating layer 1500b may extend on the first encapsulation layer 1200 and may have openings exposing portions of the first sub-redistribution pattern 1310b. In addition, the second insulating layer 1500b may have openings exposing portions of the second sub-redistribution pattern 1320b, and the first sub-redistribution pattern 1310a of the first redistribution pattern 1300a may be connected to the second sub-redistribution pattern 1320b of the second redistribution pattern 1300b through the openings.

The second package 2000 may include a package structure 2100 and the package connection terminals 2500.

The package structure 2100 may be stacked on the first package 1000 through the package connection terminals 2500. The package structure 2100 may be any one of the above-described semiconductor packages and may include a semiconductor chip.

The package connection terminal 2500 may be, for example, a solder ball or a solder bump. The package structure 2100 may be connected to the first package 1000 through the package connection terminals 2500.

The package connection terminals 2500 may be provided in the package structure 2100. The package connection terminal 2500 may include, for example, solder, tin (Sn), silver (Ag), indium (In), bismuth (Bi), antimony (Sb), copper (Cu), zinc (Zn), lead (Pb), and/or an alloy thereof. In exemplary embodiments, the package connection terminal 2500 may have a ball shape that is typically attached onto the package structure 2100. For example, the package connection terminals 2500 may be formed by positioning a solder ball on the package structure 2100 and then performing a reflow process on the solder ball. In other exemplary embodiments, the package connection terminals 2500 may also be formed to have a plate shape having a substantially uniform thickness on the surface of the second sub-redistribution pattern 1320.

Hereinafter, a method of manufacturing the semiconductor package 10k illustrated in FIG. 34 will be described.

First, a first semiconductor chip 1100 is disposed on second redistribution structures 1300b and 1500b. Specifically, the first semiconductor chip 1100 is disposed on a second insulating layer 1500b on which a second redistribution pattern 1300b is formed. The second insulating layer 1500b may be formed to have openings exposing portions of a first sub-redistribution pattern 1310b and may be formed to have openings exposing portions of a second sub-redistribution pattern 1320b.

An adhesive layer 1190 for fixing the first semiconductor chip 1100 may be provided between the second insulating layer 1500b and the first semiconductor chip 1100. The adhesive layer 1190 may include, for example, a die attach film. In addition, the adhesive layer 1190 may include a material having high thermal conductivity so that heat of the first semiconductor chip 1100 may be effectively emitted.

Next, a first encapsulation layer 1200 and the first redistribution structures 1300a, 1400, and 1500a are formed by a method similar to the method illustrated in FIGS. 29C to 291, and the external connection terminals 1900 are attached onto a second sub-redistribution pattern 1320a of a first redistribution pattern 1300a exposed by openings of a first insulating layer 1500a.

Thereafter, the resultant product is turned upside down.

Next, a package structure 2100 to which package connection terminals 2500 are attached is stacked on a first package 1000. The package connection terminals 2500 may be connected to the first sub-redistribution pattern 1310b of the second redistribution pattern 1300b exposed by the openings of the second insulating layer 1500b.

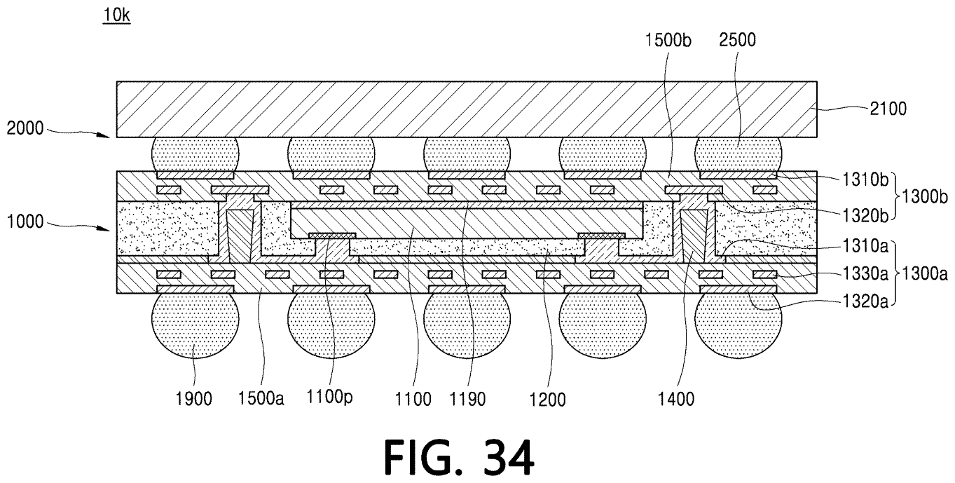

FIG. 35 is a cross-sectional view illustrating a semiconductor package according to an exemplary embodiment of the present invention.

Referring to FIG. 35, a semiconductor package 10l may include a first package 1000 and a second package 2000. The semiconductor package 10l illustrated in FIG. 35 may be a semiconductor package having a PoP structure in which the second package 2000 is attached to the first package 1000. The semiconductor package 10l illustrated in FIG. 35 may have substantially the same configuration as the semiconductor package 10k illustrated in FIG. 34. In FIG. 35, the same descriptions as those described above will be omitted or simply given.

The first package 1000 may include a first encapsulation layer 1200. The first encapsulation layer 1200 may cover a side surface and an upper surface of a first semiconductor chip 1100.

A first sub-redistribution pattern 1310 illustrated in FIG. 35 may be implemented as the first sub-redistribution pattern 131 illustrated in FIG. 1 or the first sub-redistribution pattern 131 illustrated in FIG. 12. That is, the first sub-redistribution pattern 1310 illustrated in FIG. 35 may include a first portion extending in the through hole 120H and a second portion connected to the first portion and extending on the first encapsulation layer 120, and a first thickness T₁ of the first portion of the first sub-redistribution pattern 131 may be greater than a second thickness T₂ of the first portion. In addition, the first sub-redistribution pattern 1310 illustrated in FIG. 35 may include a first conductive layer 131a disposed in the through hole 120H and a second conductive layer 131b distinct from the first conductive layer 131a and disposed on the other side surface of the first encapsulation layer 120.

The process of forming the first sub-redistribution pattern 1310 illustrated in FIG. 35 has been described above in detail, and thus, a description thereof will be omitted.

The first package 1000 may include a first insulating layer 1500a. The first insulating layer 1500a may be formed to have openings exposing portions of a second sub-redistribution pattern 1320a of a first redistribution pattern 1300a and openings exposing portions of a third sub-redistribution pattern 1330a of the first redistribution pattern 1300a. An external connection terminal 1900 may be connected to the second sub-redistribution pattern 1320a through the openings exposing portions of the second sub-redistribution pattern 1320a. A first sub-redistribution pattern 1310a may be connected to the third sub-redistribution pattern 1330a through the openings exposing portions of the third sub-redistribution pattern 1330a.

The first package 1000 may include internal connection terminals 1600. The internal connection terminals 1600 may be disposed between pads 1100p of the first semiconductor chip 1100 and the first insulating layer 1500a. The internal connection terminals 1600 may electrically connect the pads 1100p of the first semiconductor chip 1100 to the first redistribution pattern 1300a. In embodiments of the present invention, a connection between the first semiconductor chip 1100 and the external connection terminals 1900 may be made through the first redistribution pattern 1300a and the internal connection terminals 1600.

The first package 1000 may include a gap-fill layer 1700. The gap-fill layer 1700 may fill a gap between the first semiconductor chip 1100 and the first insulating layer 1500a and may surround sidewalls of the internal connection terminals 1600 disposed between the first semiconductor chip 1100 and the second semiconductor chip 2100.

Hereinafter, a method of manufacturing the semiconductor package 10l illustrated in FIG. 35 will be described.

First, a first insulating layer 1500a including a second sub-redistribution pattern 1320a of a first redistribution pattern 1300a and a third sub-redistribution pattern 1330a of the first redistribution pattern 1300a is prepared. The first insulating layer 1500a may be formed to have openings exposing portions of the second sub-redistribution pattern 1320a and openings exposing portions of the third sub-redistribution pattern 1330a.

Next, a first semiconductor chip 1100 is disposed on the first insulating layer 1500a.

Next, a first encapsulation layer 1200 and a first sub-redistribution pattern 1310a are formed by a method similar to the method illustrated in FIGS. 31B to 31E. Thereafter, a first insulating pattern 1400 is formed on the first encapsulation layer 1200 and the first sub-redistribution pattern 1310a by a method similar to the method illustrated in FIGS. 29E and 29F.

Next, second redistribution structures 1300b and 1500b are formed on the first encapsulation layer 1200. A second insulating layer 1500b may be formed to have openings exposing portions of the first sub-redistribution pattern 1310b.

Next, a package structure 2100 to which package connection terminals 2500 are attached is stacked on a first package 1000. The package connection terminals 2500 may be connected to a first sub-redistribution pattern 1310b of a second redistribution pattern 1300b exposed by the openings of the second insulating layer 1500b.

According to the technical idea of the present invention, a semiconductor package does not include inter-package connection terminals such as solder balls for electrical connection between a plurality of packages, so that a semiconductor package manufacturing process can be simplified and a thinner PoP-type semiconductor package can be provided.

Further, by forming a stress-concentrating portion of a pattern to be thick, the possibility in which a delamination phenomenon occurs is reduced, so that a semiconductor package with improved performance and improved reliability can be manufactured. In addition, a pattern portion other than the stress-concentrating portion can be formed with a constant thickness, so that a semiconductor package in which manufacturing costs are reduced and manufacturing processes are simplified can be provided.

Further, a plurality of packages can be electrically connected without inter-package connection terminals that are vulnerable to warpage, so that the reliability of a semiconductor package can be further improved.

Further, by independently forming a first conductive layer disposed on an inner surface of a through hole of a first encapsulation layer and a second conductive layer disposed on the other side surface of the first encapsulation layer, the occurrence of losses in a circuit pattern can be completely avoided, and the time and cost required for a plating process for forming the second conductive layer can be greatly reduced.

The effects according to the technical idea of the present invention are not limited to the above-mentioned effects, and other effects not mentioned may be clearly understood by those skilled in the art from the following description.

Those skilled in the art related to the present embodiment will readily appreciate that many modifications are possible without departing from the essential features of the above description. Therefore, the disclosed methods are to be considered in an illustrative sense rather than a restrictive sense. The scope of the present invention is indicated in the claims rather than the above-described description, and all differences within the scope equivalent thereto should be construed as falling within the present invention.

What is claimed is:

1. A semiconductor package comprising:
a first package including a first semiconductor chip, a first encapsulation layer covering a side surface of the first semiconductor chip, and a first redistribution pattern connected to a pad of the first semiconductor chip; and
a second package provided on the first package and including a second semiconductor chip, a second encapsulation layer covering the second semiconductor chip, and a second redistribution pattern connected to a pad of the second semiconductor chip,
wherein the first redistribution pattern is connected to the second redistribution pattern through the first encapsulation layer.

2. The semiconductor package of claim 1, wherein
the first encapsulation layer includes a first surface and a second surface opposite to each other, and a through hole passing through the first surface and the second surface,
the first redistribution pattern includes a first portion extending from the first surface to the second surface through the through hole and a second portion connected to the first portion and extending on the first surface, and
a first thickness of the first portion located on the first surface is greater than a second thickness of the first portion located on the second surface.

3. The semiconductor package of claim 1, wherein
the first encapsulation layer includes a first surface and a second surface opposite to each other, and a through hole passing through the first surface and the second surface, and
the first redistribution pattern includes a first conductive layer disposed on an inner surface of the through hole and connected to the second package, and a second conductive layer disposed on the first surface and connected to the first conductive layer and the pad of the first semiconductor chip.

4. The semiconductor package of claim 1, wherein
the second package further includes a second redistribution pattern connected to the pad of the second semiconductor chip,
the first encapsulation layer includes a first surface and a second surface opposite to each other, and a through hole passing through the first surface and the second surface, and
the first redistribution pattern is connected to the pad of the second semiconductor chip by being directly connected to the second redistribution pattern through the through hole.

5. The semiconductor package of claim 1, further comprising an electromagnetic wave shielding layer covering at least a portion of the first package and at least a portion of the second package.

6. The semiconductor package of claim 5, further comprising an outer encapsulation layer covering the first package, the second package, and the electromagnetic wave shielding layer.

7. The semiconductor package of claim 6, further comprising a lower conductive layer extending on the first package and the outer encapsulation layer,
wherein the lower conductive layer is electrically connected to the first redistribution pattern of the first package and the electromagnetic wave shielding layer.

8. The semiconductor package of claim 7, further comprising a thermal conductive film provided on the first package and the outer encapsulation layer and covering at least a portion of the lower conductive layer.
